(19) United States
(12) Patent Application Publication
(10) Pub. No.: US 2026/0031781 A1
(43) Pub. Date: Jan. 29, 2026

(54) DISCRETE POWER TRANSISTOR CONFIGURED WITH ENHANCED HARMONIC TERMINATION AND PROCESS OF IMPLEMENTING THE SAME

(71) Applicant: MACOM Technology Solutions Holdings, Inc., Lowell, MA (US)

(72) Inventors: Simon Wood, Morgan Hill, CA (US); William Pribble, Apex, NC (US)

(21) Appl. No.: 18/787,245

(22) Filed: Jul. 29, 2024

(51) Int. Cl. H03H 7/01; H01L 23/31; H01L 27/06; H01L 29/16

(52) U.S. Cl. CPC H03H 7/0115; H10D 1/20; H10D 1/68; H10D 88/00; H01L 23/3107; H10D 62/8325

(57) ABSTRACT

A packaged transistor device includes an RF signal input lead, an RF signal output lead, and a discrete transistor having a transistor structure arranged and/or formed on a substrate. The packaged transistor device also includes at least one harmonic reduction circuit arranged and/or formed on the substrate of the discrete transistor.

### FIELD OF THE DISCLOSURE

The disclosure relates to a discrete power transistor configured with enhanced harmonic termination. The disclosure further relates to a process of implementing a discrete power transistor configured with enhanced harmonic termination.

### BACKGROUND OF THE DISCLOSURE

Improved linearity during high-frequency operation is a goal in radio frequency (RF) power transistor technologies. Many factors can affect the linearity of a device in various RF power transistor technologies, including changing input and impedance with signal level, changing capacitances and their derivatives with signal levels, breakdown and substrate conduction effects, class of operation, and changing transconductance and its derivatives with bias and signal levels. In addition, in some applications, it may be desirable for an RF power transistor to achieve a desired level of linearity over a wide range of operating frequencies and/or output power levels. However, these linearity requirements in current implementations of radio frequency (RF) power transistors limit efficiency under high-frequency operation

Accordingly, radio frequency (RF) power transistor implementations having greater efficiency under high-frequency operation are needed.

### SUMMARY OF THE DISCLOSURE

The foregoing needs are met, to a great extent, by the disclosure, wherein in one aspect a discrete power transistor configured with enhanced harmonic termination is provided. Further, the foregoing needs are met, to a great extent, by the disclosure, wherein in one aspect a process of implementing a discrete power transistor configured with enhanced harmonic termination is provided.

In one aspect, a packaged transistor device includes an RF signal input lead. The packaged transistor device in addition includes an RF signal output lead. The packaged transistor device moreover includes a discrete transistor having a transistor structure arranged and/or formed on a substrate. The packaged transistor device also includes at least one harmonic reduction circuit arranged and/or formed on the substrate of the discrete transistor.

In one aspect, a process includes providing an RF signal input lead. The process in addition includes providing an RF signal output lead. The process moreover includes forming and arranging a discrete transistor having a transistor structure on a substrate. The process also includes forming and arranging at least one harmonic reduction circuit on the substrate of the discrete transistor.

In one aspect, a packaged transistor device includes an RF signal input lead. The packaged transistor device in addition includes an RF signal output lead. The packaged transistor device moreover includes a discrete transistor having a transistor structure arranged and/or formed on a substrate. The packaged transistor device also includes at least one harmonic reduction circuit arranged and/or formed on the substrate of the discrete transistor. The packaged transistor device further includes where a structure of the at least one harmonic reduction circuit is arranged at least partially on the substrate, is arranged at least partially on the transistor structure, and/or is arranged at least partially on the substrate and the transistor structure.

In one aspect, a process includes providing an RF signal input lead. The process in addition includes providing an RF signal output lead. The process moreover includes forming and arranging a discrete transistor having a transistor structure on a substrate. The process also includes forming and arranging at least one harmonic reduction circuit on the substrate of the discrete transistor. The process further includes where a structure of the at least one harmonic reduction circuit is arranged at least partially on the substrate, is arranged at least partially on the transistor structure, and/or is arranged at least partially on the substrate and the transistor structure.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a packaged transistor device according to aspects of the disclosure.

FIG. 2 illustrates another packaged transistor device according to aspects of the disclosure.

FIG. 3 illustrates another packaged transistor device according to aspects of the disclosure.

FIG. 4 illustrates another packaged transistor device according to aspects of the disclosure.

FIG. 5 illustrates another packaged transistor device according to aspects of the disclosure.

FIG. 6 illustrates another packaged transistor device according to aspects of the disclosure.

FIG. 7 illustrates a cross-sectional view of an exemplary implementation of the discrete transistor according to aspects of the disclosure.

FIG. 8 illustrates a cross-sectional view of an exemplary implementation of the at least one capacitor according to aspects of the disclosure.

FIG. 9 illustrates a cross-sectional view of an exemplary implementation of the at least one inductive element according to aspects of the disclosure.

FIG. 10 illustrates a top view of the at least one inductive element according to FIG. 9.

FIG. 11 illustrates a cross-sectional view of an exemplary combined implementation of the at least one capacitor and the at least one inductive element according to aspects of the disclosure.

FIG. 12 illustrates an exemplary implementation of the transistor structure that may include a plurality of unit cell transistors in accordance with an aspect of the disclosure.

FIG. 13 is a schematic cross-sectional view taken along line XIII-XIII of FIG. 12.

FIG. 14 illustrates a partial schematic circuit diagram of the discrete transistor according to aspects of the disclosure.

FIG. 15 illustrates a partial schematic circuit diagram of the discrete transistor according to aspects of the disclosure.

FIG. 16 illustrates a partial schematic circuit diagram of the discrete transistor according to aspects of the disclosure.

FIG. 17 illustrates a partial schematic circuit diagram of the discrete transistor according to aspects of the disclosure.

FIG. 18 illustrates a partial schematic circuit diagram of the discrete transistor according to aspects of the disclosure.

FIG. 19 illustrates an exemplary implementation of the discrete transistor according to aspects of the disclosure.

FIG. 20 illustrates an exemplary implementation of the discrete transistor according to aspects of the disclosure.

FIG. 21 illustrates an exemplary implementation of the discrete transistor according to aspects of the disclosure.

FIG. 22 illustrates an exemplary implementation of the discrete transistor according to aspects of the disclosure.

FIG. 23 illustrates an exemplary implementation of the discrete transistor according to aspects of the disclosure.

FIG. 24 illustrates an exemplary implementation of the discrete transistor according to aspects of the disclosure.

FIG. 25 illustrates an exemplary implementation of the discrete transistor according to aspects of the disclosure.

FIG. 26 and FIG. 27 illustrate simulated results of the harmonic reduction circuit and/or the harmonic reduction circuit implementing bandpass topology versus the harmonic reduction circuit and/or the harmonic reduction circuit implementing low-pass topology.

FIG. 28 illustrates a perspective view of a package according to the disclosure.

FIG. 29 illustrates a cross-sectional view of the package according to FIG. 28.

FIG. 30 illustrates a perspective view of a package according to the disclosure.

FIG. 31 shows a process of making a package according to the disclosure.

### DETAILED DESCRIPTION

The disclosure will now be described with reference to the drawing figures, in which like reference numerals refer to like parts throughout. Aspects of the disclosure advantageously provide a discrete power transistor configured with enhanced harmonic termination. Further, aspects of the disclosure advantageously provide a process of implementing a discrete power transistor configured with enhanced harmonic termination.

Currently, second harmonic terminations are achieved through the use of a chip and wire technique. Forming a shunt inductor to ground through a separate physical capacitor. This technique works well from 0.4 GHz-3.0 GHz, but becomes practically difficult to implement above 3 GHz.

The disclosed discrete power transistor with enhanced harmonic termination may implement a capacitor buried underneath a wirebond pad, a capacitor under a wirebond with an inductor in a white space, a capacitor and inductor in a white space, an inductor on top of a capacitor in a white space, an inductor printed in a white space available between wirebond pads, and/or the like. It may be important with this approach that a final die size either does not grow, or the increase is acceptable for performance gains at higher frequency, where a second harmonic (2F0) termination could not otherwise be implemented.

In aspects, a second harmonic match may be implemented by absorbing an inductor into a fundamental match as a bandpass structure. This may make a physical realization of this component as compact as possible. Using a bandpass match provides for higher performance.

In particular, current technology utilizes a chip and wire with manufacturing variability. Realization of this technique monolithically will further improve performance and will reduce variability.

In aspects, implementation of the disclosed discrete power transistor with enhanced harmonic termination results in limited or no increase in chip size. In aspects, the disclosed discrete power transistor with enhanced harmonic termination may implement an inductor on capacitor configuration. In aspects, the disclosed discrete power transistor with enhanced harmonic termination may implement a bond on capacitor configuration.

In aspects, the disclosed discrete power transistor with enhanced harmonic termination may have applications in cellular infrastructure base station radios, aerospace and defense telecommunications and radar. And wherever the need for enhanced efficiency in a transistor based design may exist.

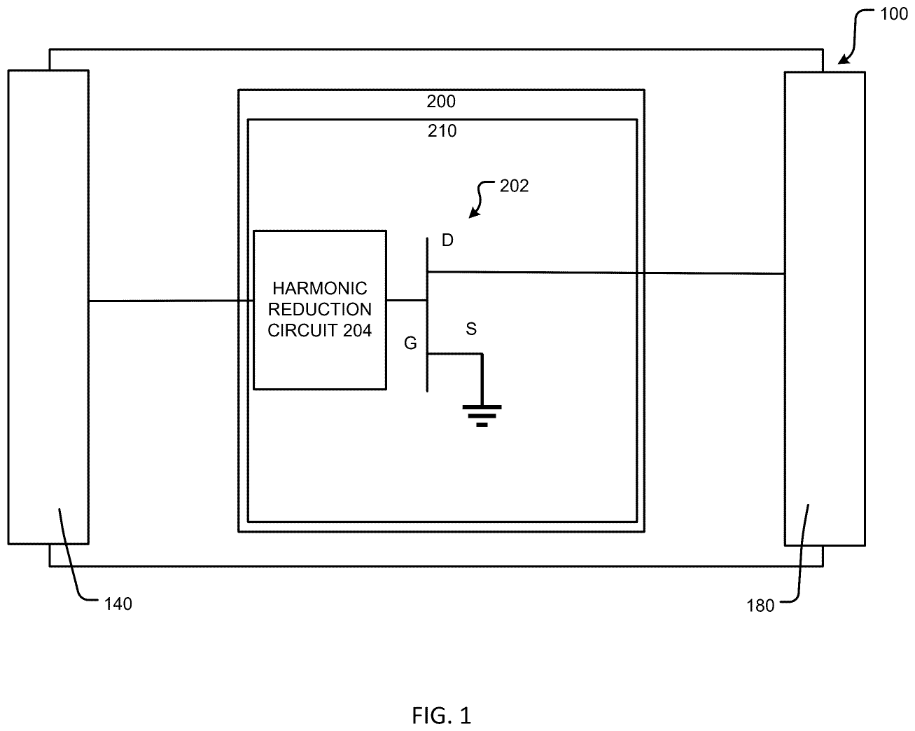

FIG. 1 illustrates a packaged transistor device according to aspects of the disclosure.

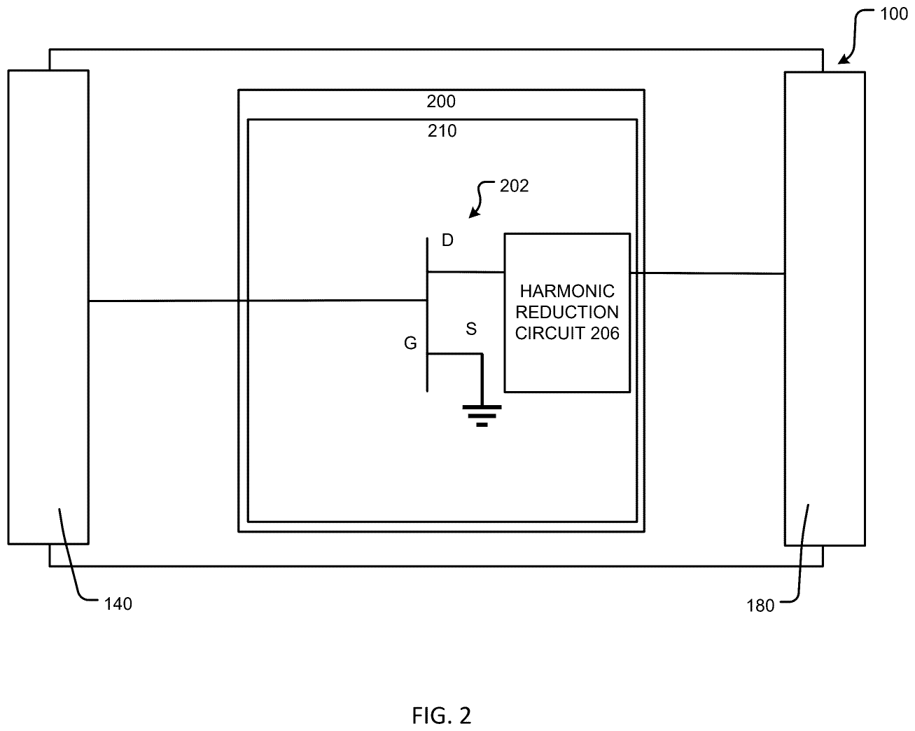

FIG. 2 illustrates another packaged transistor device according to aspects of the disclosure.

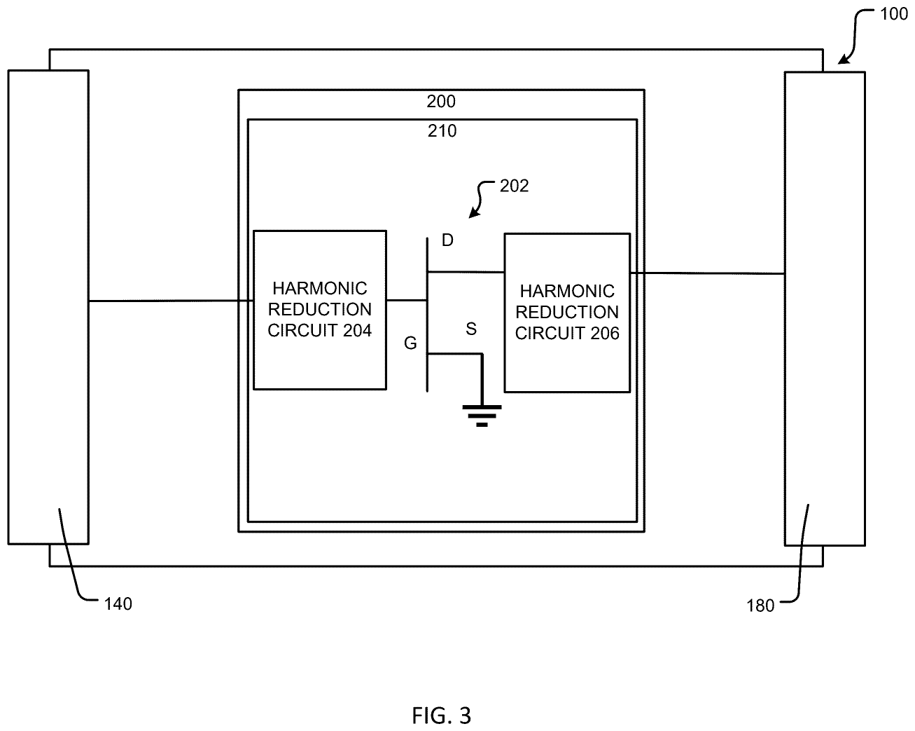

FIG. 3 illustrates another packaged transistor device according to aspects of the disclosure.

In particular, FIG. 1, FIG. 2, and FIG. 3 Illustrate a packaged transistor device 100. In aspects, the packaged transistor device 100 may include a discrete transistor 200, an RF signal input lead 140, an RF signal output lead 180, and/or the like.

The discrete transistor 200 may include a transistor structure 202 and an enhanced harmonic structure as further described herein. In particular, the transistor structure 202 may be arranged and/or formed on a substrate 210 and the enhanced harmonic structure may be arranged and/or formed on the substrate 210.

With reference to FIG. 1 and FIG. 3, the discrete transistor 200 may further include a harmonic reduction circuit 204. In aspects, the harmonic reduction circuit 204 and the transistor structure 202 may be arranged and/or formed on the substrate 210. In aspects, the harmonic reduction circuit 204 may be configured as the enhanced harmonic structure, an enhanced harmonic termination structure, an enhanced harmonic circuit, an enhanced harmonic termination circuit structure, and/or the like.

With reference to FIG. 2 and FIG. 3, the discrete transistor 200 may further include a harmonic reduction circuit 206. In aspects, the harmonic reduction circuit 206 and the transistor structure 202 may be arranged and/or formed on the substrate 210. In aspects, the harmonic reduction circuit 206 may be configured as the enhanced harmonic structure, an enhanced harmonic termination structure, an enhanced harmonic circuit, an enhanced harmonic termination circuit structure, and/or the like.

In aspects, the packaged transistor device 100 may include the harmonic reduction circuit 204. In this aspect, the harmonic reduction circuit 204 and the transistor structure 202 may be arranged and/or formed on the substrate 210.

In aspects, the packaged transistor device 100 may include the harmonic reduction circuit 206. In this aspect, the harmonic reduction circuit 206 and the transistor structure 202 may be arranged and/or formed on the substrate 210.

In aspects, the packaged transistor device 100 may include the harmonic reduction circuit 204 and the harmonic reduction circuit 206. In this aspect, the harmonic reduction circuit 204, the harmonic reduction circuit 206, and the transistor structure 202 may be arranged and/or formed on the substrate 210.

In aspects, the harmonic reduction circuit 204 and/or the harmonic reduction circuit 206 may implement a capacitor buried underneath a wirebond pad of the discrete transistor 200; and 2) an inductor printed in a white space available between wirebond pads of the discrete transistor 200. It may be important with this approach that a final die size of the discrete transistor 200 either does not grow, or the increase is acceptable for performance gains at higher frequency, where a second harmonic (2F0) could not usually be used.

In aspects, the harmonic reduction circuit 204 and/or the harmonic reduction circuit 206 may be implemented by absorbing an inductor into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond on capacitor configuration.

In aspects, the packaged transistor device 100 and/or the discrete transistor 200 may be configured to connect the RF signal input lead 140 to a control electrode of the discrete transistor 200 and/or the transistor structure 202. For example, the packaged transistor device 100 and/or the discrete transistor 200 may be configured to connect the RF signal input lead 140 to a gate of a FET; or the packaged transistor device 100 and/or the discrete transistor 200 may be configured to connect the RF signal input lead 140 to a base of a bipolar transistor.

In aspects, the discrete transistor 200 may be configured to connect the harmonic reduction circuit 204 to a control electrode of the transistor structure 202. For example, the discrete transistor 200 may be configured to connect the harmonic reduction circuit 204 to a gate of a FET; or the discrete transistor 200 may be configured to connect the harmonic reduction circuit 204 to a base of a bipolar transistor. In aspects, the packaged transistor device 100 may be configured to connect the RF signal input lead 140 to the harmonic reduction circuit 204 of the discrete transistor 200.

In aspects, the packaged transistor device 100 and/or the discrete transistor 200 may be configured to connect the RF signal output lead 180 to an output electrode of the discrete transistor 200 and/or the transistor structure 202. For example, the packaged transistor device 100 and/or the discrete transistor 200 may be configured to connect the RF signal output lead 180 to a drain of a FET; or the packaged transistor device 100 and/or the discrete transistor 200 may be configured to connect the RF signal output lead 180 to a collector or emitter of a bipolar transistor. The RF signal input lead 140 and the RF signal output lead 180 may extend outside the packaged transistor device 100. The source of the discrete transistor 200 may be grounded.

In aspects, the discrete transistor 200 may be configured to connect the harmonic reduction circuit 206 to an output electrode of the transistor structure 202. For example, the discrete transistor 200 may be configured to connect the harmonic reduction circuit 206 to a drain D of a FET; or the discrete transistor 200 may be configured to connect the harmonic reduction circuit 206 to a collector or emitter of a bipolar transistor. In aspects, the discrete transistor 200 may be configured to connect the RF signal output lead 180 to the harmonic reduction circuit 206.

In aspects, the substrate 210 may be made of Silicon Carbide (SiC). In another aspect, the substrate 210 may be GaAs, GaN, or other material suitable for the applications described herein. In another aspect, the substrate 210 may include sapphire, spinel, ZnO, silicon, and/or any other material capable of supporting growth of Group III-nitride materials.

In aspects, the packaged transistor device 100 may be implemented as a RF package, a RF amplifier package, a RF power amplifier package, a RF power transistor package, a RF power amplifier transistor package, a power transistor package, and/or the like as described herein.

According to aspects of the disclosure, the packaged transistor device 100 implementing the discrete transistor 200 having the harmonic reduction circuit 204 and/or the harmonic reduction circuit 206 within the discrete transistor 200 may be configured such that harmonic reduction can occur before the signal reaches the RF signal output lead 180. Thus, the packaged transistor device 100 implementing the discrete transistor 200 having the harmonic reduction circuit 204 and/or the harmonic reduction circuit 206 within the discrete transistor 200 may improve linearity of the packaged transistor device 100 by reducing second and/or higher order harmonics within the discrete transistor 200 itself. Placing the harmonic reduction circuit 204 and/or the harmonic reduction circuit 206 within the discrete transistor 200 may improve the performance across a broad range of frequencies and/or output power levels. Furthermore, design of an external output matching circuit may be simplified, since the signal output from the packaged transistor device 100 may have lower energy at harmonic frequencies.

In aspects shown in FIG. 1 and FIG. 3, the packaged transistor device 100 may include the discrete transistor 200 and the discrete transistor 200 may include the harmonic reduction circuit 204 connected to a control electrode of the transistor structure 202. The discrete transistor 200 implementing the harmonic reduction circuit 204 may be configured to reduce the energy at a harmonic frequency, such as the second harmonic frequency, in the input signal.

In aspects illustrated in FIG. 2 and FIG. 3, the discrete transistor 200 may be configured with the harmonic reduction circuit 206 at the output (drain) of the transistor structure 202. The harmonic reduction circuit 206 may be configured to reduce the energy at a harmonic frequency, such as the second harmonic frequency, in the output signal.

In aspects, the discrete transistor 200 may be implemented as a gallium nitride (GaN) silicon carbide (SiC) transistor. In aspects, the discrete transistor 200 may be implemented as one or more of a wide band-gap semiconductor device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a component such as a General-Purpose Broadband component, a Telecom component, a L-Band component, a S-Band component, a X-Band component, a C-Band component, a Ku-Band component, a Satellite Communications component, a Doherty configuration, and/or the like. In aspects of the packaged transistor device 100, the discrete transistor 200 may be implemented as a RF power transistor and may include a plurality of transistor cells operating in parallel. In aspects, the discrete transistor 200 may include laterally diffused MOSFETS (LDMOSFET) or other semiconductor devices, such as bipolar devices, MESFET devices, HBTs and HEMT devices. In aspects, the discrete transistor 200 may be made using narrow or wide bandgap semiconductors. In aspects, the discrete transistor 200 may include silicon LDMOS and/or bipolar transistors, and/or III-V devices such as GaAs MESFETs, InGaP HBTs, GaN HEMT devices, GaN bipolar transistors, and/or the like

In aspects, the packaged transistor device 100 may be mounted on an application interface, such as a printed circuit board (not shown). An external output matching circuit may also be mounted on the application interface. A bias/RF diplexer (not shown) may be connected to the external output matching circuit to connect the transistor output to an RF output. Furthermore, a DC power supply (not shown) may be connected to the RF signal output lead 180. It will be appreciated that the base of the packaged transistor device 100 can refer to any structural member on which the discrete transistor 200 is mounted, and accordingly can correspond to a substrate, flange, die carrier, or the like.

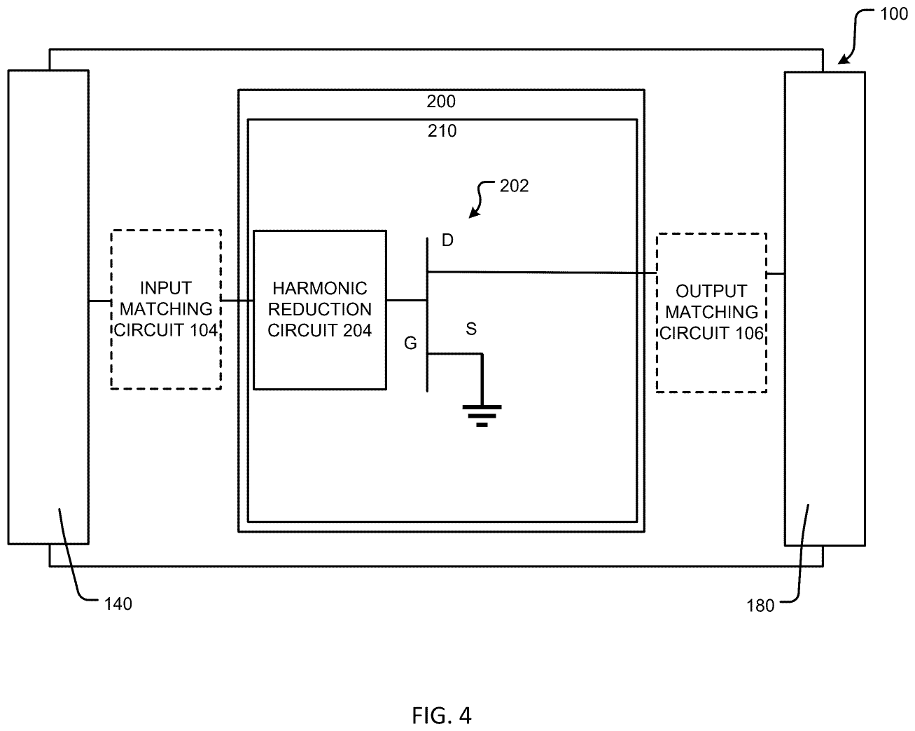

FIG. 4 illustrates another packaged transistor device according to aspects of the disclosure.

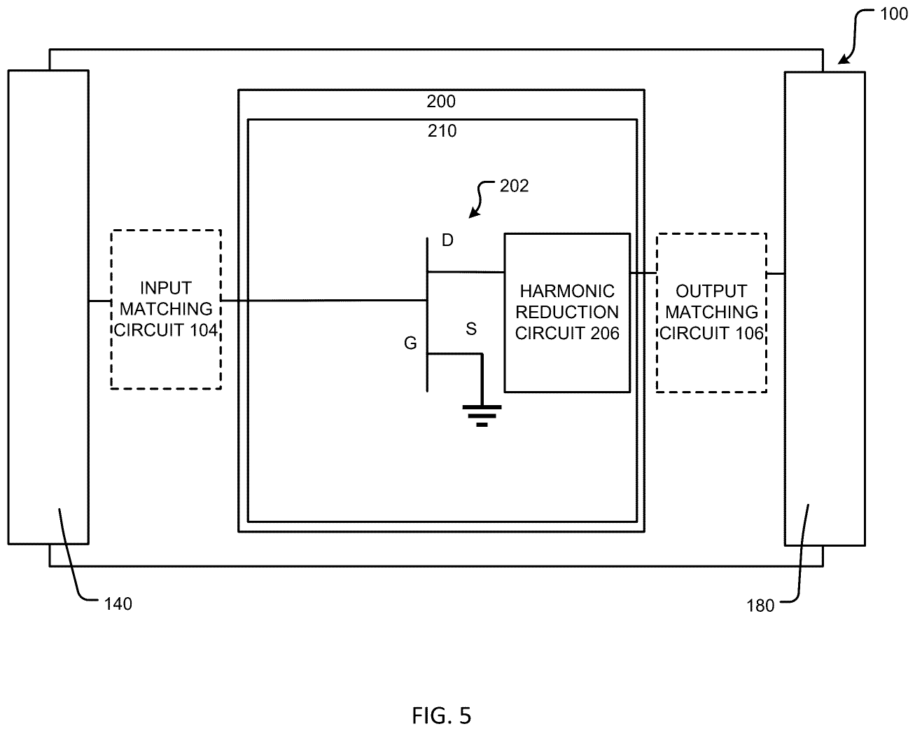

FIG. 5 illustrates another packaged transistor device according to aspects of the disclosure.

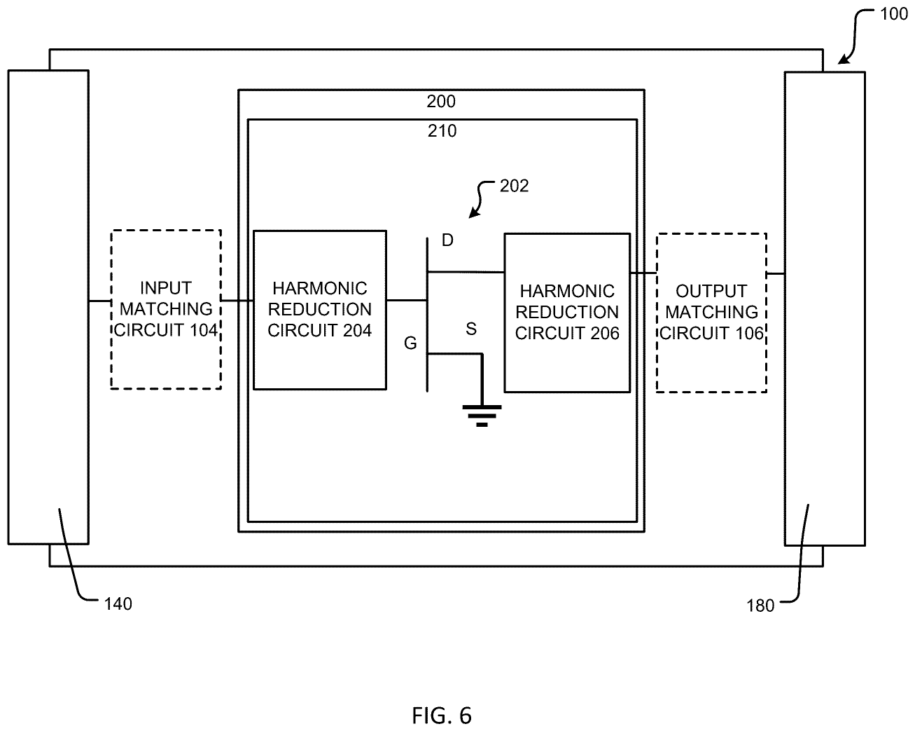

FIG. 6 illustrates another packaged transistor device according to aspects of the disclosure.

In particular, FIG. 4, FIG. 5, and FIG. 6 illustrates that the packaged transistor device 100 may further include an input matching circuit 104 and/or an output matching circuit 106. However, other implementations of the packaged transistor device 100 may only include the input matching circuit 104; and other implementations of the packaged transistor device 100 may only include the output matching circuit 106.

With reference to FIG. 4 and FIG. 6, the discrete transistor 200 may further include the harmonic reduction circuit 204. With reference to FIG. 5 and FIG. 6, the discrete transistor 200 may further include the harmonic reduction circuit 206.

In aspects, the packaged transistor device 100 and/or the discrete transistor 200 may be configured to connect the input matching circuit 104 to a control electrode of the discrete transistor 200 and/or the transistor structure 202. For example, the packaged transistor device 100 and/or the discrete transistor 200 may be configured to connect the input matching circuit 104 to a gate of a FET; or the packaged transistor device 100 and/or the discrete transistor 200 may be configured to connect the input matching circuit 104 to a base of a bipolar transistor.

In aspects, the packaged transistor device 100 and/or the discrete transistor 200 may be configured to connect the output matching circuit 106 to an output electrode of the discrete transistor 200 and/or the transistor structure 202. For example, the packaged transistor device 100 and/or the discrete transistor 200 may be configured to connect the output matching circuit 106 to a drain of a FET; or the packaged transistor device 100 and/or the discrete transistor 200 may be configured to connect the output matching circuit 106 to a collector or emitter of a bipolar transistor.

In aspects shown in FIG. 4 and FIG. 6, the packaged transistor device 100 may include the input matching circuit 104 and the discrete transistor 200 may include the harmonic reduction circuit 204 connected to a control electrode of the transistor structure 202. The packaged transistor device 100 implementing the discrete transistor 200 and the harmonic reduction circuit 204 may be configured to reduce the energy at a harmonic frequency, such as the second harmonic frequency, in the input signal.

In aspects shown in FIG. 5 and FIG. 6, the packaged transistor device 100 may include the output matching circuit 106 and the discrete transistor 200 may be configured with the harmonic reduction circuit 206 at the output (drain) of the transistor structure 202. The harmonic reduction circuit 206 may be configured to reduce the energy at a harmonic frequency, such as the second harmonic frequency, in the output signal.

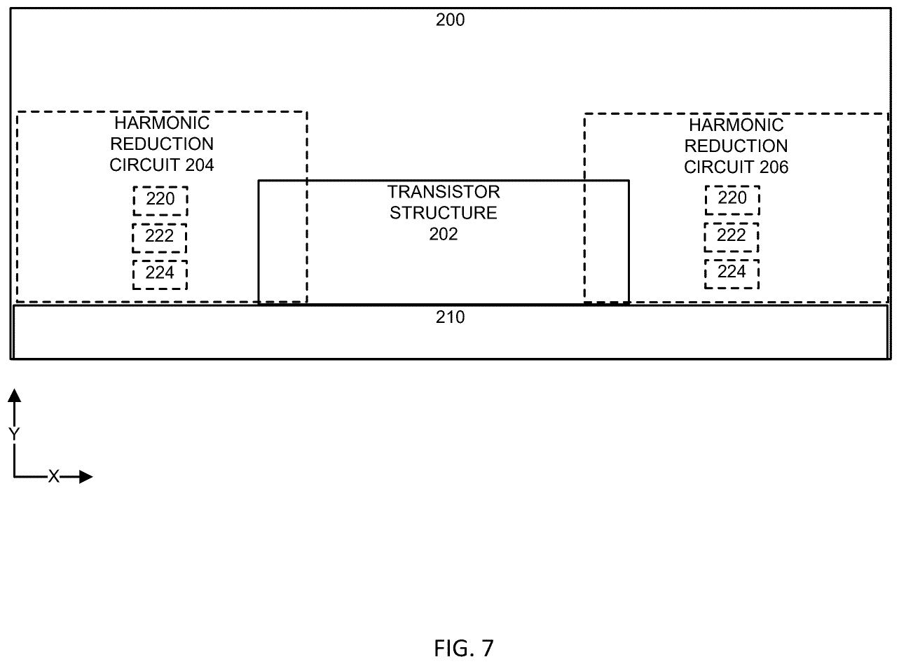

FIG. 7 illustrates a cross-sectional view of an exemplary implementation of the discrete transistor according to aspects of the disclosure.

In particular, FIG. 7 illustrates an exemplary implementation of the discrete transistor 200. In aspects, the discrete transistor 200 may implement the harmonic reduction circuit 204, the discrete transistor 200 may implement the harmonic reduction circuit 206, and/or the discrete transistor 200 may implement the harmonic reduction circuit 204 and the harmonic reduction circuit 206.

In aspects, a structure of the harmonic reduction circuit 204 may be arranged at least partially on the substrate 210, may be arranged at least partially on the transistor structure 202, and/or may be arranged at least partially on the substrate 210 and the transistor structure 202. In aspects, the harmonic reduction circuit 204 may include at least one inductive element 220, at least one capacitor 222, at least one resistor 224, and/or the like.

In aspects, a structure of the harmonic reduction circuit 206 may be arranged at least partially on the substrate 210, may be arranged at least partially on the transistor structure 202, and/or may be arranged at least partially on the substrate 210 and the transistor structure 202. In aspects, the harmonic reduction circuit 206 may include at least one inductive element 220, at least one capacitor 222, at least one resistor 224, and/or the like.

In aspects, a structure of the transistor structure 202 may be arranged at least partially on the substrate 210, may be arranged at least partially on the harmonic reduction circuit 204, may be arranged at least partially on the harmonic reduction circuit 206, and/or may be arranged at least partially on the substrate 210, the harmonic reduction circuit 204, and/or the harmonic reduction circuit 206.

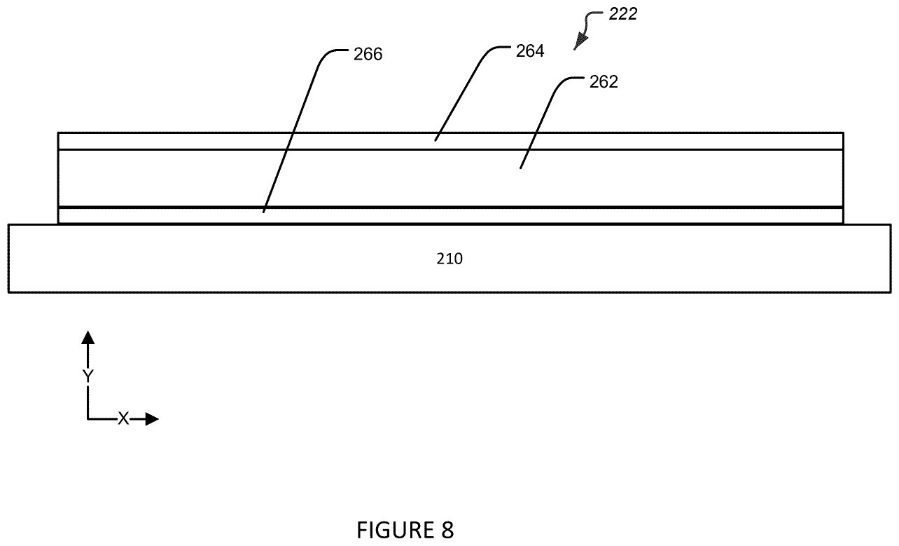

FIG. 8 illustrates a cross-sectional view of an exemplary implementation of the at least one capacitor according to aspects of the disclosure.

In particular, FIG. 8 illustrates an exemplary implementation of the at least one capacitor 222. In aspects, the at least one capacitor 222 may include at least one dielectric layer 262, at least one capacitor top metal 264, at least one capacitor bottom metal 266, and/or the like. In particular, the at least one capacitor 222 may form a capacitor with the at least one capacitor top metal 264 and the at least one capacitor bottom metal 266 having the at least one dielectric layer 262 therebetween. In aspects, a structure of the at least one capacitor 222 may be arranged at least partially on the substrate 210, may be arranged at least partially on the transistor structure 202, and/or may be arranged at least partially on the substrate 210 and the transistor structure 202.

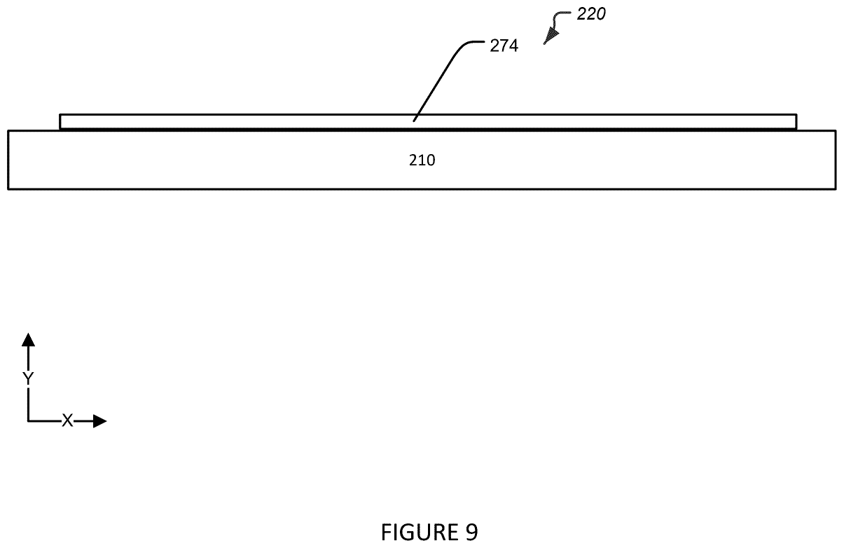

FIG. 9 illustrates a cross-sectional view of an exemplary implementation of the at least one inductive element according to aspects of the disclosure.

In particular, FIG. 9 illustrates an exemplary implementation of the at least one inductive element 220. In aspects, the at least one inductive element 220 may include at least one inductor metal 274 and/or the like. In particular, the at least one inductive element 220 may form an inductor by arrangement of the at least one inductor metal 274 on the substrate 210. In aspects, a structure of the at least one inductive element 220 may be arranged at least partially on the substrate 210, may be arranged at least partially on the transistor structure 202, and/or may be arranged at least partially on the substrate 210 and the transistor structure 202.

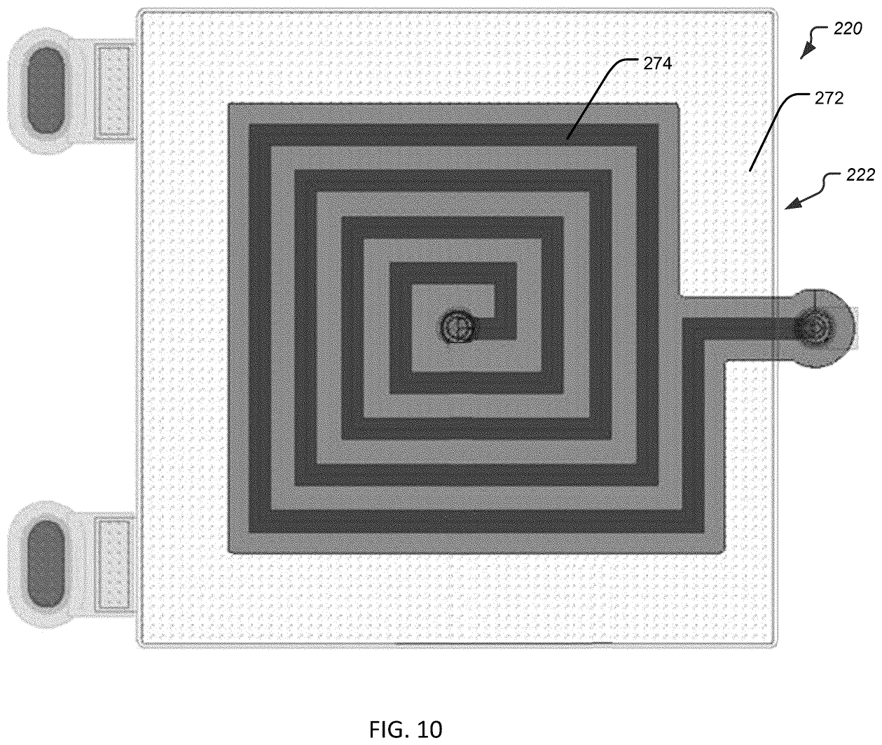

FIG. 10 illustrates a top view of an exemplary combined implementation of the at least one capacitor and the at least one inductive element according to aspects of the disclosure.

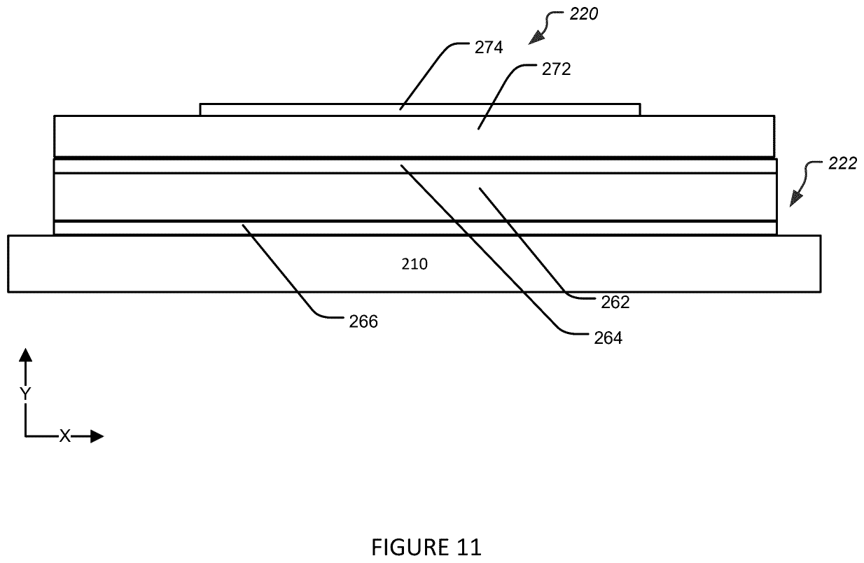

FIG. 11 illustrates a cross-sectional view of the exemplary combined implementation of the at least one capacitor and the at least one inductive element according to FIG. 10.

As illustrated in FIG. 10, in aspects the at least one inductive element 220 may implement a spiral structural configuration of the at least one inductor metal 274. Further, the at least one capacitor 222 may form a capacitor with the at least one capacitor top metal 264 and the at least one capacitor bottom metal 266 having the at least one dielectric layer 262 therebetween as illustrated in FIG. 11; and the at least one inductive element 220 may form an inductor by arrangement of the at least one inductor metal 274 on at least one dielectric layer 272 as illustrated in FIG. 10 and FIG. 11.

In aspects, a structure of the at least one capacitor 222 may be arranged at least partially on the substrate 210, may be arranged at least partially on the transistor structure 202, may be arranged at least partially on the substrate 210 and the transistor structure 202, and/or may be arranged at least partially on the at least one inductive element 220 (not shown). In aspects, a structure of the at least one inductive element 220 may be arranged at least partially on the substrate 210, may be arranged at least partially on the transistor structure 202, may be arranged at least partially on the substrate 210 and the transistor structure 202, and/or may be arranged at least partially on the at least one capacitor 222.

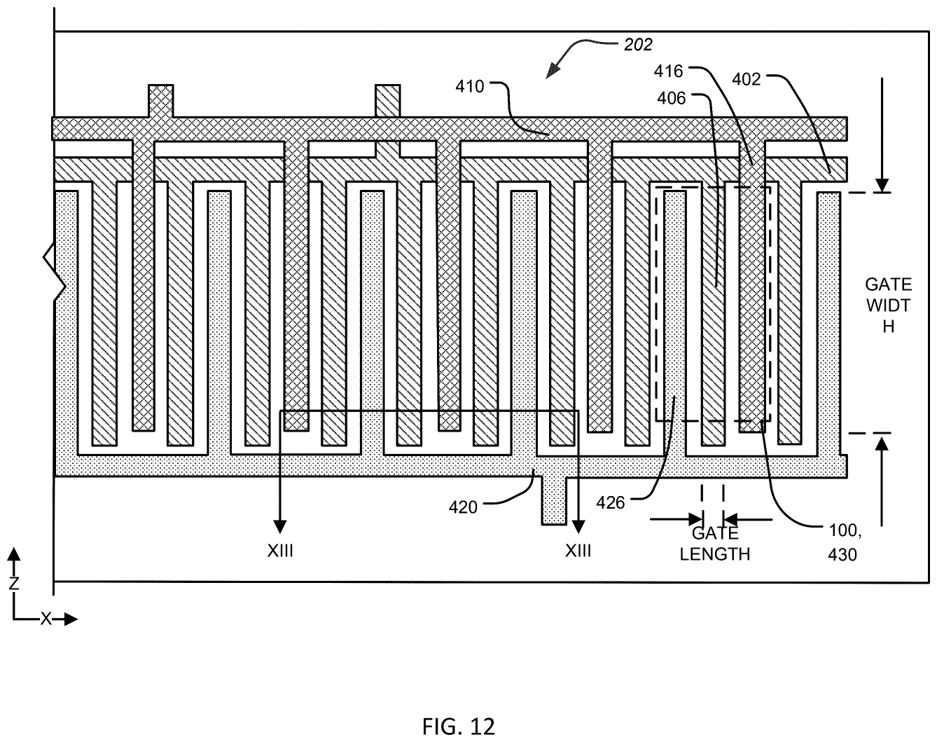

FIG. 12 illustrates an exemplary implementation of the transistor structure that may include a plurality of unit cell transistors in accordance with an aspect of the disclosure.

In particular, FIG. 12 illustrates an exemplary implementation of the transistor structure 202 that may include a plurality of unit cells 430. In aspects, the transistor structure 202 may include a gate bus 402 that may be connected to a plurality of gate fingers 406 that may extend in parallel in a first direction (e.g., the Z-direction indicated in FIG. 12) that connect to or form part of a gate. A source bus 410 may be connected to a plurality of parallel ones of source contacts 416 that connect to or form part of a source. In some aspects, the source bus 410 may be connected to a ground voltage node on an underside of the transistor structure 202. A drain bus 420 may be connected to a plurality of drain contacts 426 that connect to or form part of a drain.

As can be seen in FIG. 12, each gate finger 406 may run along the Z-direction between a pair of adjacent ones of the source contact 416 and the drain contact 426. The transistor structure 202 may include the plurality of unit cells 430, where each one of the plurality of unit cells 430 includes an implementation of a transistor. One of the plurality of unit cells 430 is illustrated by the dashed box in FIG. 12, and includes a gate finger 406 that extends between adjacent ones of the source contact 416 and the drain contact 426.

The “gate width” refers to the distance by which the gate finger 406 overlaps with its associated one of the source contact 416 and drain contact 426 in the Z-direction. That is, “width” of a gate finger 406 refers to the dimension of the gate finger 406 that extends in parallel to and adjacent an implementation of the source contact 416 and the drain contact 426 (the distance along the Z-direction). Each of the plurality of unit cells 430 may share one of the source contact 416 and/or the drain contact 426 with one or more adjacent ones of the plurality of unit cells 430. Although a particular number of the of the plurality of unit cells 430 is illustrated in FIG. 12, it will be appreciated that the transistor structure 202 may include more or less of the plurality of unit cells 430.

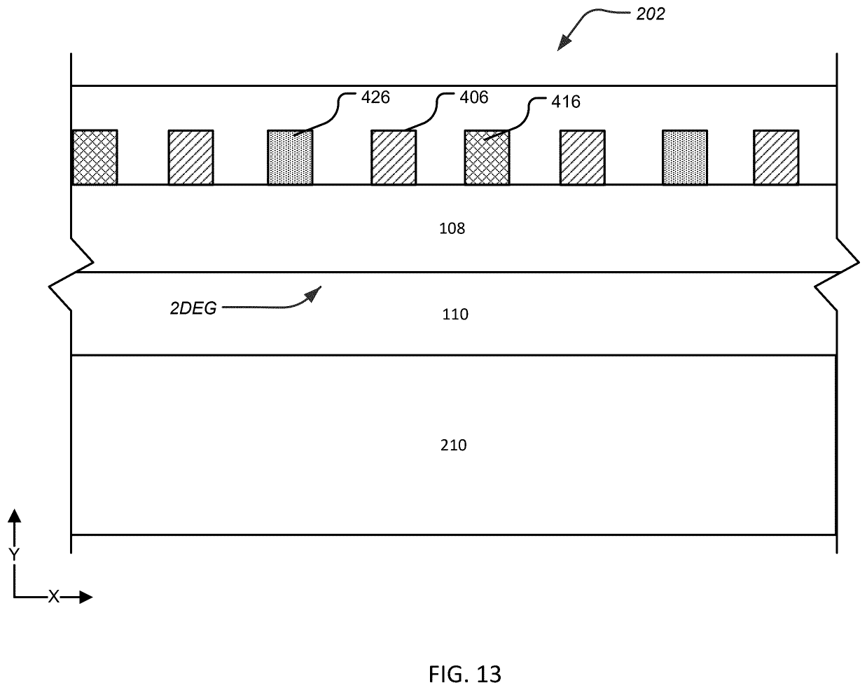

FIG. 13 is a schematic cross-sectional view taken along line XIII-XIII of FIG. 12.

Referring to FIG. 13, the transistor structure 202 may include the substrate 210, a buffer layer 110, a barrier layer 108, and/or the like. The source contact 416 and the drain contact 426 may be on the barrier layer 108. The gate fingers 406 may be on the substrate 210 between the source contacts 416 and the drain contacts 426. While the gate fingers 406, the source contact 416, and the drain contacts 426 are all shown schematically in FIG. 12 and FIG. 13 as having a similar “dimension,” it will be appreciated that each may have different shapes and dimensions consistent with the disclosure.

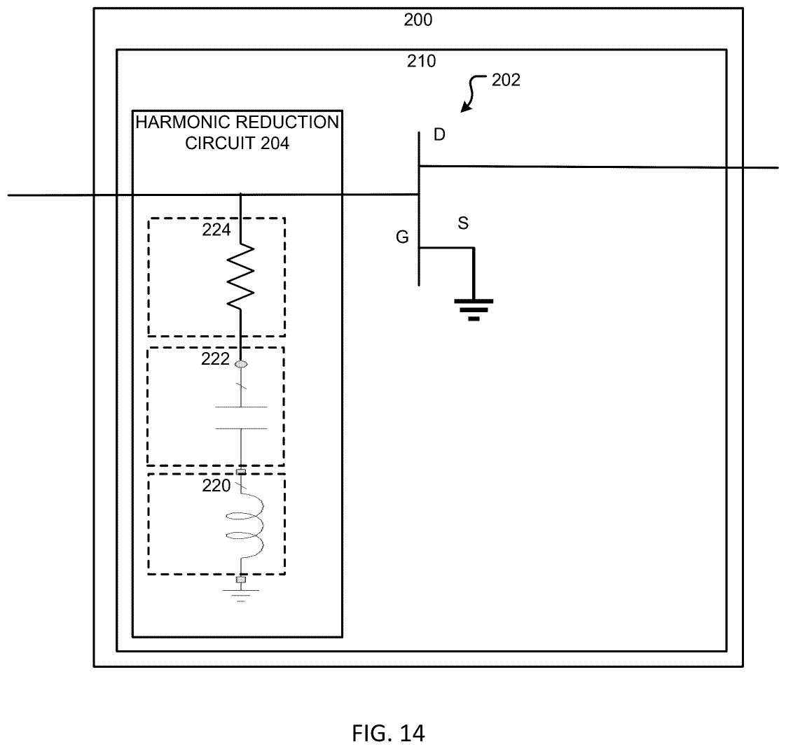

FIG. 14 illustrates a partial schematic circuit diagram of the discrete transistor according to aspects of the disclosure.

In particular, FIG. 14 illustrates a partial schematic circuit diagram of the discrete transistor 200 that includes the harmonic reduction circuit 204 and the transistor structure 202 arranged on the substrate 210. In aspects, the harmonic reduction circuit 204 may be connected to the control terminal (gate) of the transistor structure 202. In aspects illustrated in FIG. 14, the harmonic reduction circuit 204 may include the at least one inductive element 220 in series with the at least one capacitor 222. More specifically, the harmonic reduction circuit 204 illustrated in FIG. 14 may be implemented as an RCL circuit (resistor-capacitor-inductor circuit). In other aspects not illustrated, the harmonic reduction circuit 204 may be implemented as an RLC (resistor-inductor-capacitor circuit), an LRC circuit (inductor-resistor-capacitor circuit), a circuit having any arrangement of at least one inductor, resistor, and capacitor and/or the like.

In aspects, the inductance of the at least one inductive element 220 and the capacitance of the at least one capacitor 222 may be selected so as to provide a bandpass implementation. In aspects, the at least one capacitor 222 may be implemented as a shunt capacitor. In aspects, the inductance of the at least one inductive element 220 and the capacitance of the at least one capacitor 222 may be selected so as to provide a short circuit and/or low impedance path to ground for signals at a harmonic frequency, such as the second harmonic frequency, relative to the fundamental operating frequency of the discrete transistor 200 at the input to the transistor structure 202.

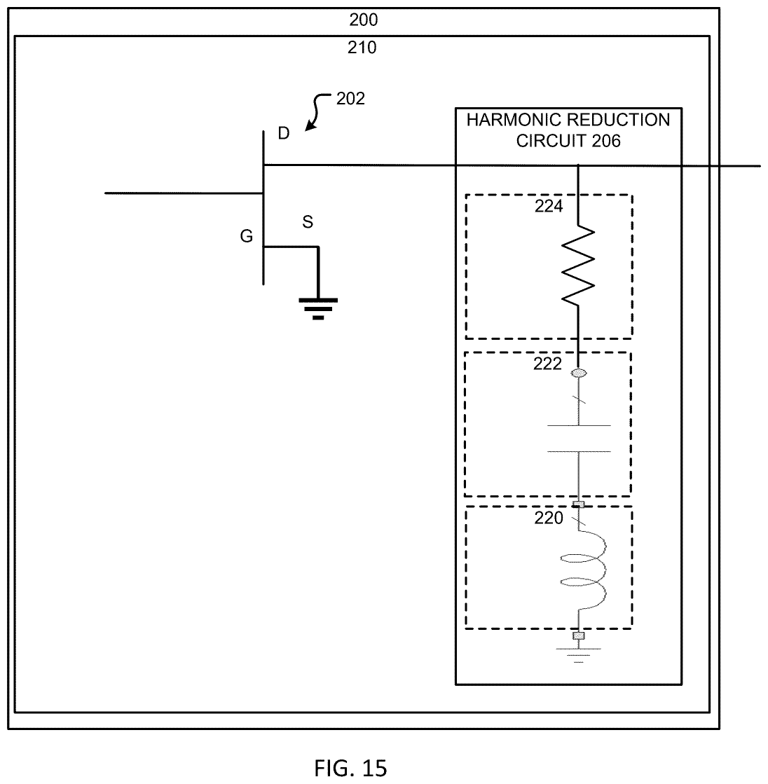

FIG. 15 illustrates a partial schematic circuit diagram of the discrete transistor according to aspects of the disclosure.

In particular, FIG. 15 illustrates a partial schematic circuit diagram of the discrete transistor 200 that includes the harmonic reduction circuit 206 and the transistor structure 202 arranged on the substrate 210. In aspects, the harmonic reduction circuit 206 may be coupled to an output terminal (drain) of the transistor structure 202.

In aspects, the inductance of the at least one inductive element 220 and the capacitance of the at least one capacitor 222 may be selected so as to provide a bandpass implementation. In aspects, the harmonic reduction circuit 206 may include the at least one inductive element 220 in series with the at least one capacitor 222, which may be implemented as a shunt capacitor. The inductance of the at least one inductive element 220 and the capacitance of the at least one capacitor 222 may be selected so as to provide short circuits and/or low impedance paths to ground for signals at a harmonic frequency, such as the second harmonic frequency, relative to the fundamental operating frequency of the discrete transistor 200 at the output of the discrete transistor 200.

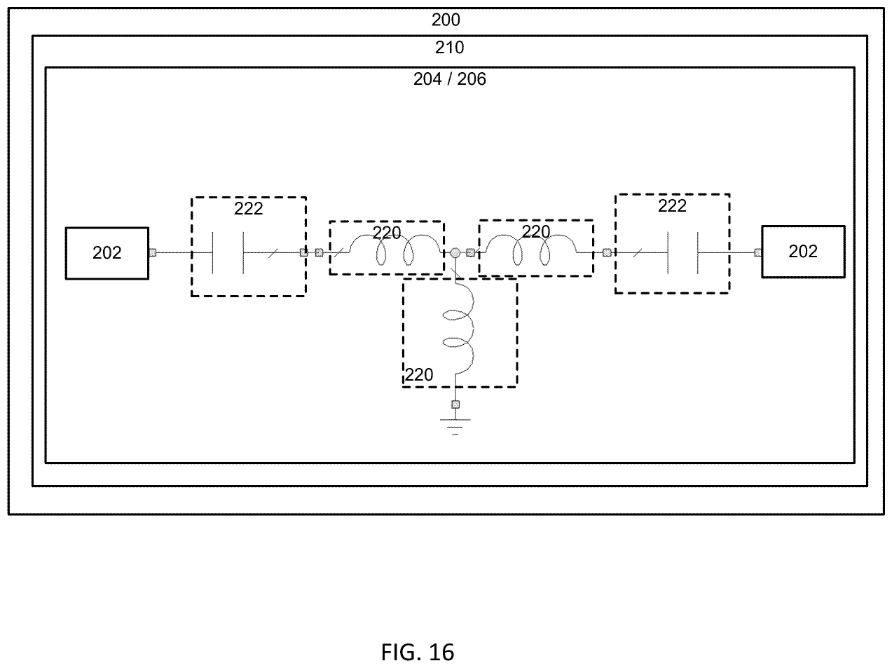

FIG. 16 illustrates a partial schematic circuit diagram of the discrete transistor according to aspects of the disclosure.

In particular, FIG. 16 illustrates a partial schematic circuit diagram of the discrete transistor 200 that includes the harmonic reduction circuit 206 and/or the harmonic reduction circuit 204 and the transistor structure 202 arranged on the substrate 210. In aspects, the inductance of the at least one inductive element 220 and the capacitance of the at least one capacitor 222 may be selected so as to provide a bandpass implementation.

In aspects, the harmonic reduction circuit 206 and/or the harmonic reduction circuit 204 may include an implementation of the at least one inductive element 220 in series with an implementation of the at least one capacitor 222 and the harmonic reduction circuit 206 and/or the harmonic reduction circuit 204 may include another implementation of the at least one inductive element 220 in series with another implementation of the at least one capacitor 222. Additionally, the harmonic reduction circuit 206 and/or the harmonic reduction circuit 204 may include a further implementation of the at least one inductive element 220 in series with an implementation of the at least one capacitor 222.

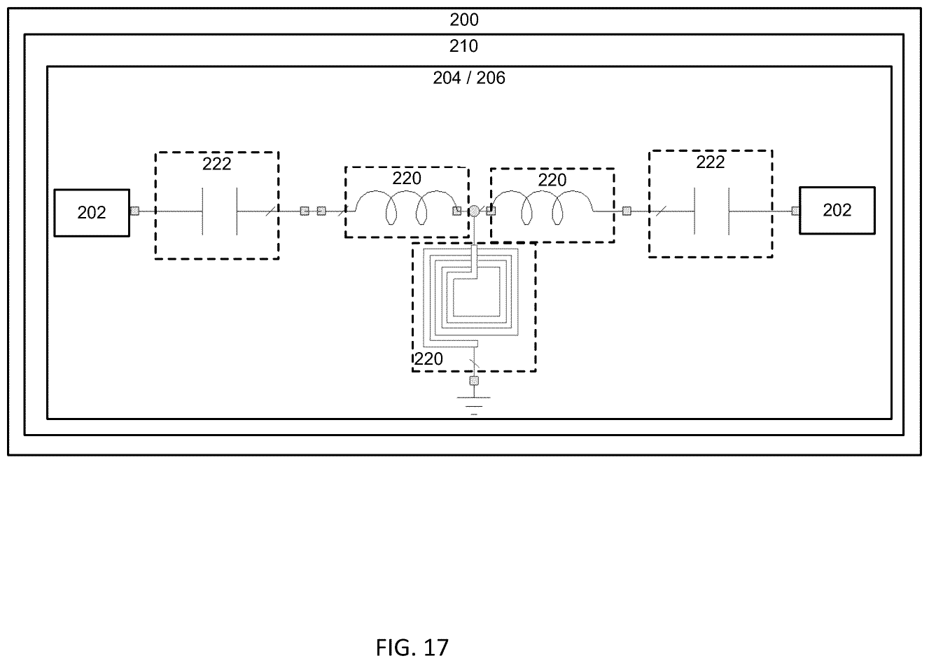

FIG. 17 illustrates a partial schematic circuit diagram of the discrete transistor according to aspects of the disclosure.

In particular, FIG. 17 illustrates a partial schematic circuit diagram of the discrete transistor 200 that includes the harmonic reduction circuit 206 and/or the harmonic reduction circuit 204 and the transistor structure 202 arranged on the substrate 210. In aspects, the inductance of the at least one inductive element 220 and the capacitance of the at least one capacitor 222 may be selected so as to provide a bandpass implementation.

In aspects, the harmonic reduction circuit 206 and/or the harmonic reduction circuit 204 may include an implementation of the at least one inductive element 220 in series with an implementation of the at least one capacitor 222 and the harmonic reduction circuit 206 and/or the harmonic reduction circuit 204 may include another implementation of the at least one inductive element 220 in series with another implementation of the at least one capacitor 222. Additionally, the harmonic reduction circuit 206 and/or the harmonic reduction circuit 204 may include a further implementation of the at least one inductive element 220 in series with an implementation of the at least one capacitor 222. As illustrated in FIG. 17, in aspects the at least one inductive element 220 may implement a spiral structural configuration of the at least one inductor metal 274.

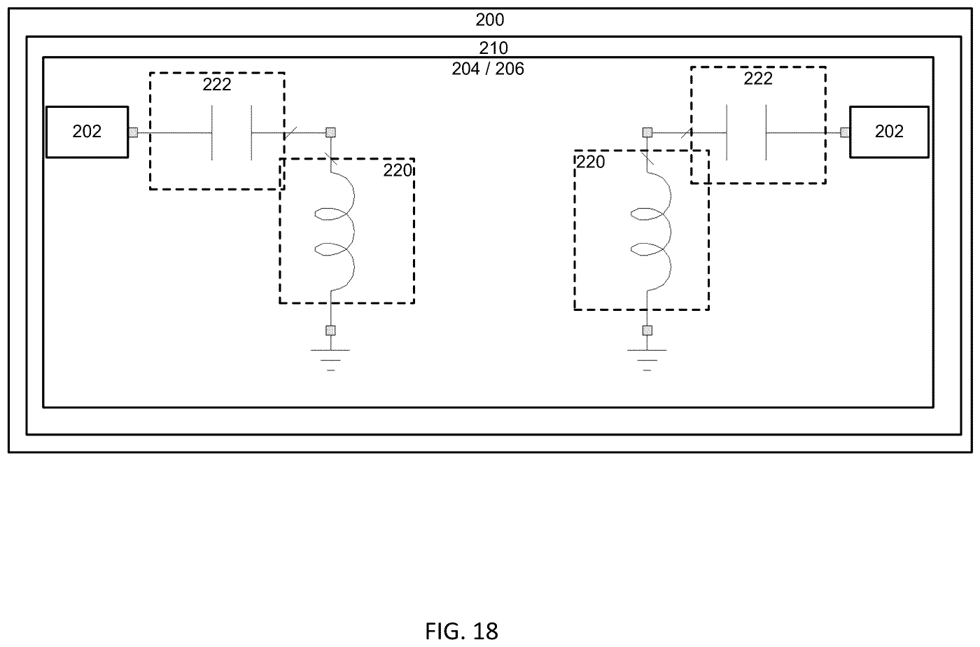

FIG. 18 illustrates a partial schematic circuit diagram of the discrete transistor according to aspects of the disclosure.

In particular, FIG. 18 illustrates a partial schematic circuit diagram of the discrete transistor 200 that includes the harmonic reduction circuit 206 and/or the harmonic reduction circuit 204 and the transistor structure 202 arranged on the substrate 210. In aspects, the inductance of the at least one inductive element 220 and the capacitance of the at least one capacitor 222 may be selected so as to provide a bandpass implementation.

In aspects, the harmonic reduction circuit 206 and/or the harmonic reduction circuit 204 may include the at least one inductive element 220 in series with the at least one capacitor 222; and the harmonic reduction circuit 206 and/or the harmonic reduction circuit 204 may include another implementation of the at least one inductive element 220 in series with another implementation of the at least one capacitor 222.

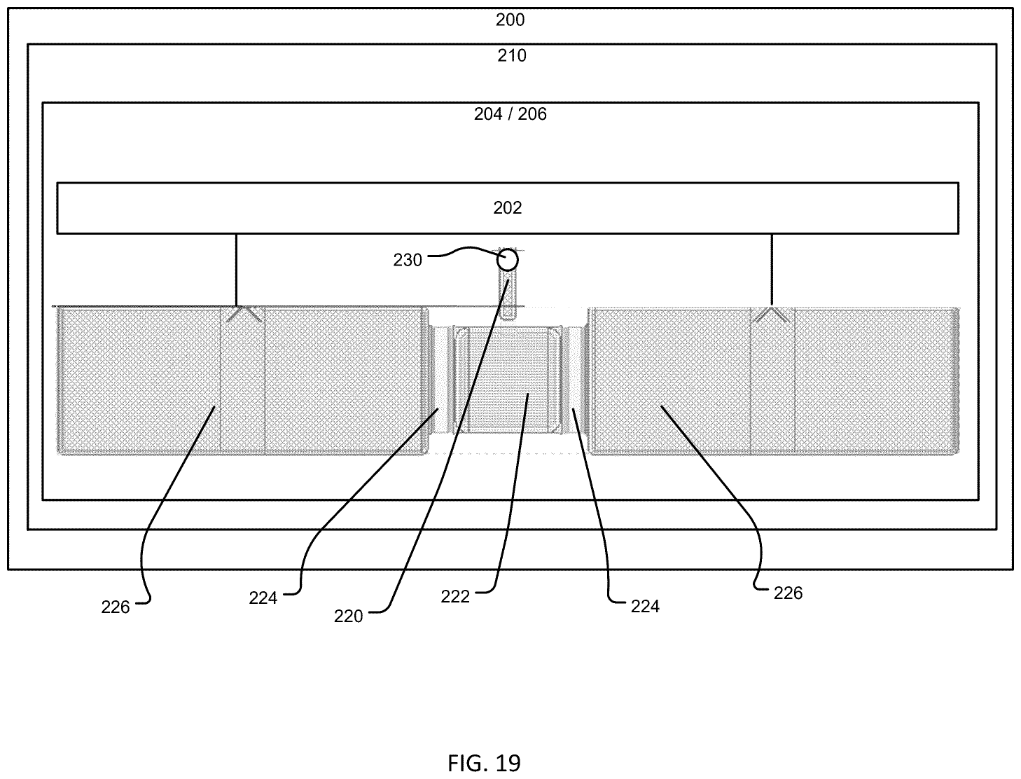

FIG. 19 illustrates an exemplary implementation of the discrete transistor according to aspects of the disclosure.

In particular, FIG. 19 illustrates an exemplary implementation of the discrete transistor 200 with partial details and arrangements of the transistor structure 202 and the harmonic reduction circuit 206 and/or the harmonic reduction circuit 204.

In aspects, the discrete transistor 200 may include one or more bond pads 226. In aspects, the one or more bond pads 226 may connect to the input matching circuit 104, the output matching circuit 106, the RF signal input lead 140, the RF signal output lead 180, and/or the like. In aspects, the discrete transistor 200 may include one or more vias 230.

In aspects, the harmonic reduction circuit 204 and/or the harmonic reduction circuit 206 may implement the at least one capacitor 222 in a whitespace between the one or more bond pads 226 of the discrete transistor 200. In aspects, the at least one inductive element 220 may be printed in a white space available adjacent the at least one capacitor 222 and/or implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond on the at least one capacitor 222.

As further illustrated in FIG. 19, the at least one capacitor 222 may be arranged on the substrate 210 adjacent the at least one resistor 224. Further, the at least one resistor 224 may be arranged on the substrate 210 adjacent the one or more bond pads 226 and the at least one capacitor 222. In aspects, the at least one resistor 224 may connect the one or more bond pads 226 to the at least one capacitor 222.

Additionally, the at least one inductive element 220 may be arranged on the substrate 210 adjacent the at least one capacitor 222. In aspects, the at least one inductive element 220 may be connected to the at least one capacitor 222 and the one or more vias 230.

In aspects, the harmonic reduction circuit 204 and/or the harmonic reduction circuit 206 may implement the at least one capacitor 222 buried underneath the one or more bond pads 226 of the discrete transistor 200. In aspects, the at least one inductive element 220 may be printed in a white space available between implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond on the at least one capacitor 222.

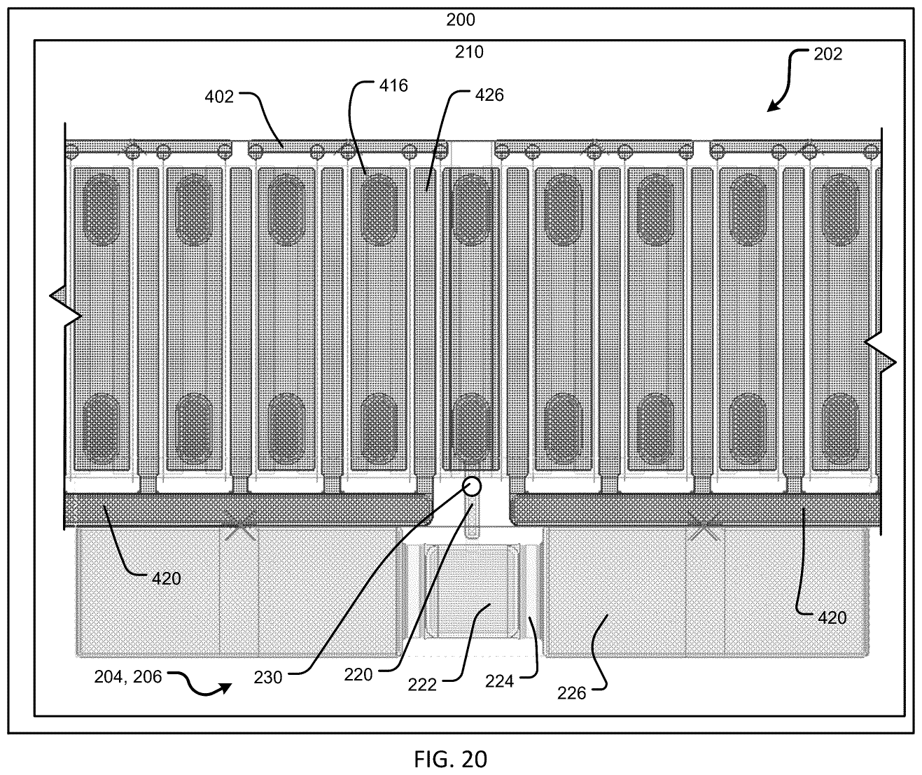

FIG. 20 illustrates an exemplary implementation of the discrete transistor according to aspects of the disclosure.

In particular, FIG. 20 illustrates an exemplary implementation of the discrete transistor 200 generally consistent with FIG. 19 and further illustrates an exemplary construction of the transistor structure 202 implemented as a FET.

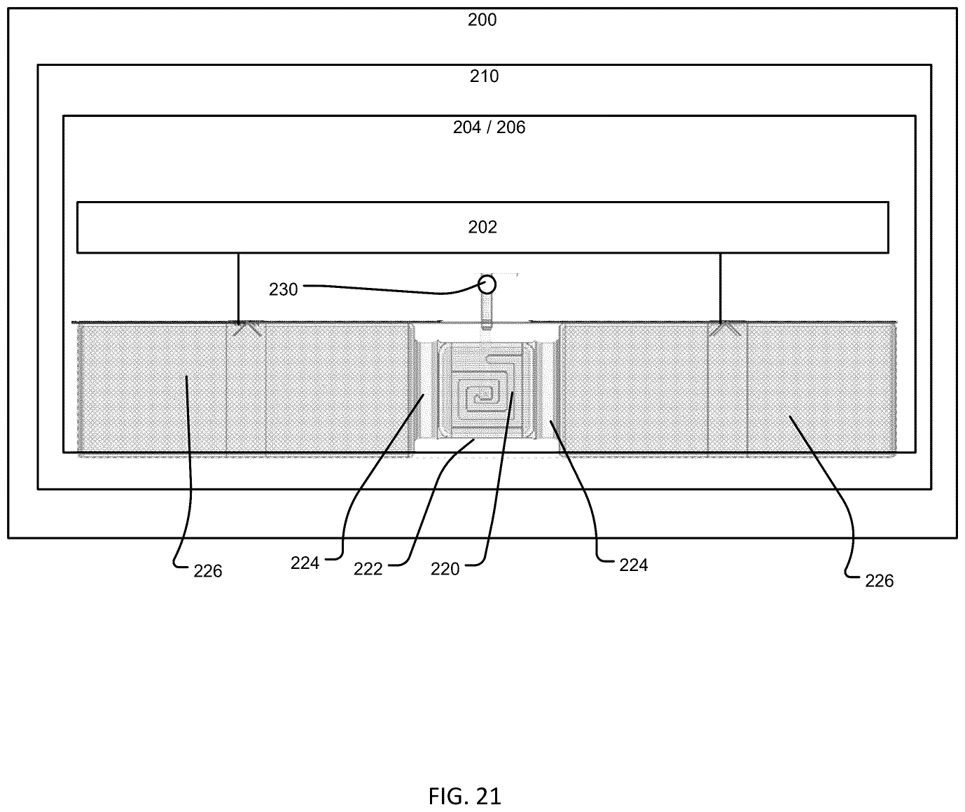

FIG. 21 illustrates an exemplary implementation of the discrete transistor according to aspects of the disclosure.

In particular, FIG. 21 illustrates an exemplary implementation of the discrete transistor 200 with partial details and arrangements of the transistor structure 202 and the harmonic reduction circuit 206 and/or the harmonic reduction circuit 204.

As further illustrated in FIG. 21, the at least one capacitor 222 may be arranged on the substrate 210 adjacent the at least one resistor 224. Further, the at least one resistor 224 may be arranged on the substrate 210 adjacent the one or more bond pads 226 and the at least one capacitor 222. In aspects, the at least one resistor 224 may connect the one or more bond pads 226 to the at least one capacitor 222.

Additionally, the at least one inductive element 220 may be arranged on the substrate 210 under the at least one capacitor 222. In aspects, the at least one inductive element 220 may be connected to the at least one capacitor 222 and the one or more vias 230.

In aspects, the harmonic reduction circuit 204 and/or the harmonic reduction circuit 206 may implement the at least one capacitor 222 buried underneath the one or more bond pads 226 of the discrete transistor 200. In aspects, the at least one inductive element 220 may be printed in a white space available between implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement the one or more bond pads 226 adjacent the at least one capacitor 222.

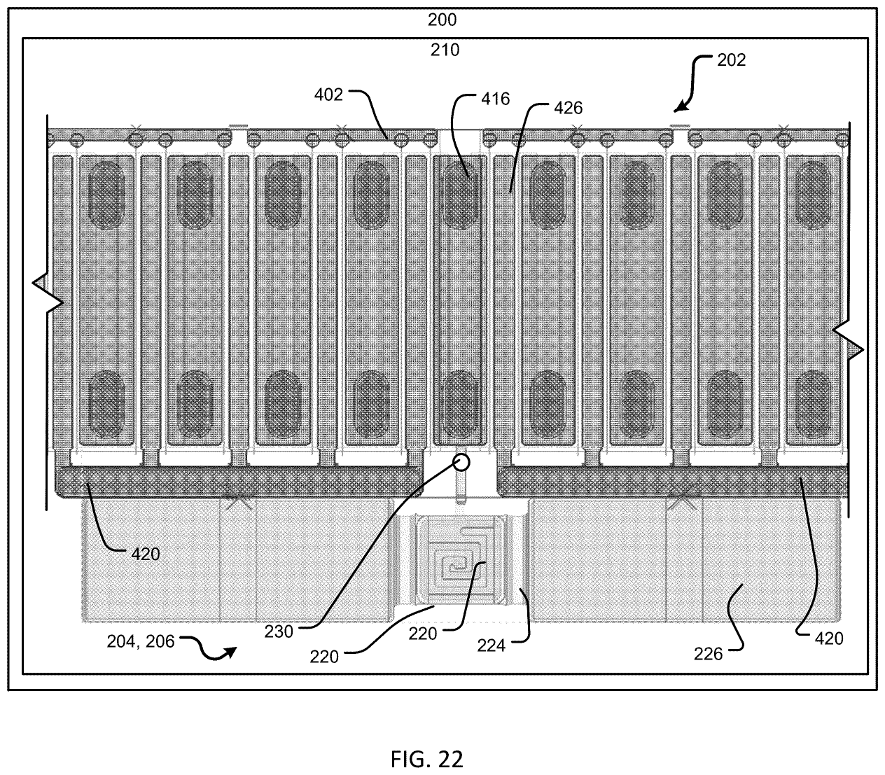

FIG. 22 illustrates an exemplary implementation of the discrete transistor according to aspects of the disclosure.

In particular, FIG. 22 illustrates an exemplary implementation of the discrete transistor 200 consistent with FIG. 21 and further illustrates an exemplary construction of the transistor structure 202 implemented as a FET.

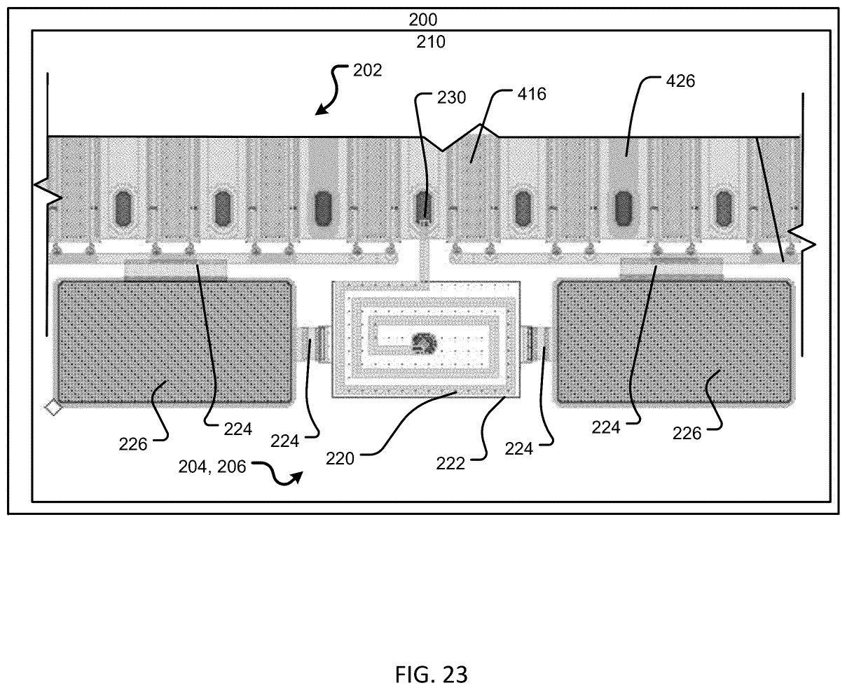

FIG. 23 illustrates an exemplary implementation of the discrete transistor according to aspects of the disclosure.

In particular, FIG. 23 illustrates an exemplary implementation of the discrete transistor 200 with partial details and arrangements of the transistor structure 202 and the harmonic reduction circuit 206 and/or the harmonic reduction circuit 204.

As further illustrated in FIG. 23, the at least one capacitor 222 may be arranged on the substrate 210 adjacent the at least one resistor 224. Further, the at least one resistor 224 may be arranged on the substrate 210 adjacent the one or more bond pads 226 and the at least one capacitor 222. In aspects, the at least one resistor 224 may connect the one or more bond pads 226 to the at least one capacitor 222.

Additionally, the at least one inductive element 220 may be arranged on the substrate 210 adjacent the at least one capacitor 222. In aspects, the at least one inductive element 220 may be connected to the at least one capacitor 222 and the one or more vias 230. In aspects, the one or more bond pads 226 may be connected to the gate bus 402 through another implementation of the at least one resistor 224.

In aspects, the harmonic reduction circuit 204 and/or the harmonic reduction circuit 206 may implement the at least one capacitor 222 buried underneath the one or more bond pads 226 of the discrete transistor 200. In aspects, the at least one inductive element 220 may be printed in a white space available between implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond the at least one capacitor 222.

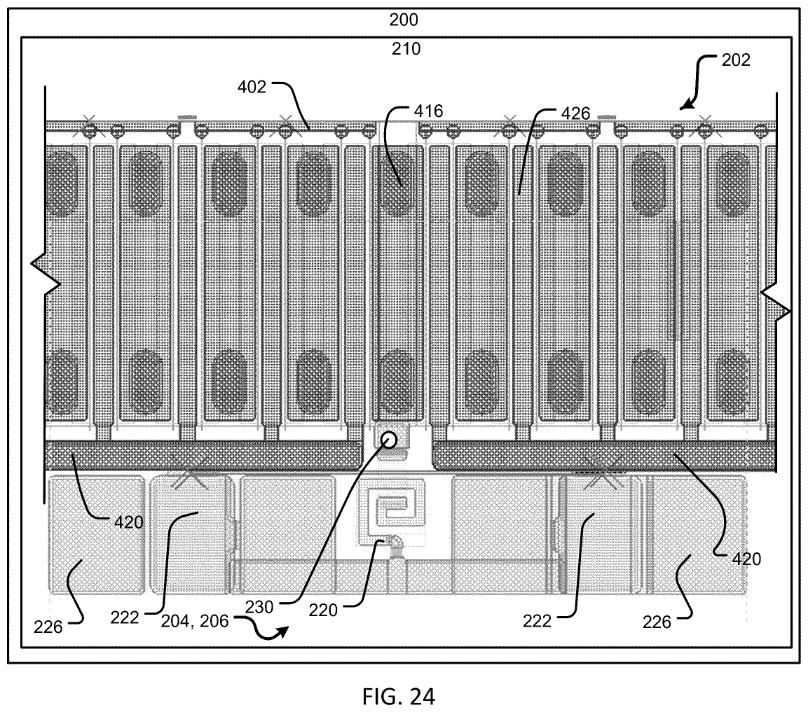

FIG. 24 illustrates an exemplary implementation of the discrete transistor according to aspects of the disclosure.

In particular, FIG. 24 illustrates an exemplary implementation of the discrete transistor 200 with partial details and arrangements of the transistor structure 202 and the harmonic reduction circuit 206 and/or the harmonic reduction circuit 204.

As further illustrated in FIG. 24, the at least one capacitor 222 may be arranged on the substrate 210 under the one or more bond pads 226. Additionally, the at least one inductive element 220 may be arranged on the substrate 210 adjacent the at least one capacitor 222. In aspects, the at least one inductive element 220 may be connected to the at least one capacitor 222 and the one or more vias 230. In aspects, the one or more bond pads 226 may be connected to the drain bus 420.

In aspects, the harmonic reduction circuit 204 and/or the harmonic reduction circuit 206 may implement the at least one capacitor 222 buried underneath the one or more bond pads 226 of the discrete transistor 200. In aspects, the at least one inductive element 220 may be printed in a white space available between implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond the at least one capacitor 222.

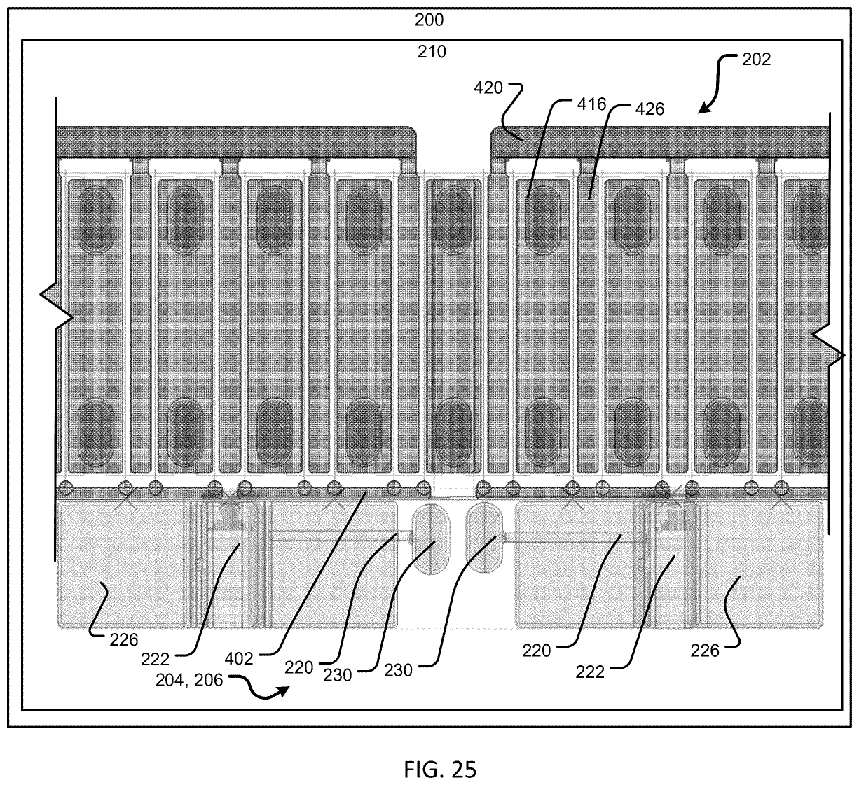

FIG. 25 illustrates an exemplary implementation of the discrete transistor according to aspects of the disclosure.

In particular, FIG. 25 illustrates an exemplary implementation of the discrete transistor 200 with partial details and arrangements of the transistor structure 202 and the harmonic reduction circuit 206 and/or the harmonic reduction circuit 204.

As further illustrated in FIG. 25, the at least one capacitor 222 may be arranged on the substrate 210 buried under the one or more bond pads 226. Additionally, the at least one inductive element 220 may be arranged on the substrate 210 adjacent the at least one capacitor 222. In aspects, the at least one inductive element 220 may be connected to the at least one capacitor 222 and the one or more vias 230. In aspects, the one or more bond pads 226 may be connected to the gate bus 402.

In aspects, the harmonic reduction circuit 204 and/or the harmonic reduction circuit 206 may implement the at least one capacitor 222 buried underneath the one or more bond pads 226 of the discrete transistor 200. In aspects, the at least one inductive element 220 may be printed in a white space available between implementations of the one or more bond pads 226 of the discrete transistor 200.

In aspects, the harmonic reduction circuit 204 and/or the harmonic reduction circuit 206 may be implemented by absorbing the at least one inductive element 220 into a fundamental match as a bandpass structure. This may make a physical realization of the discrete transistor 200 as compact as possible. Using a bandpass match provides for higher performance.

In aspects, implementation of the discrete transistor 200 with the harmonic reduction circuit 204 and/or the harmonic reduction circuit 206 as disclosed may result in limited or no increase in chip size of the discrete transistor 200. In aspects, the harmonic reduction circuit 204 and/or the harmonic reduction circuit 206 may implement an inductor on capacitor configuration. In aspects, the harmonic reduction circuit 204 and/or the harmonic reduction circuit 206 may implement a bond the at least one capacitor 222.

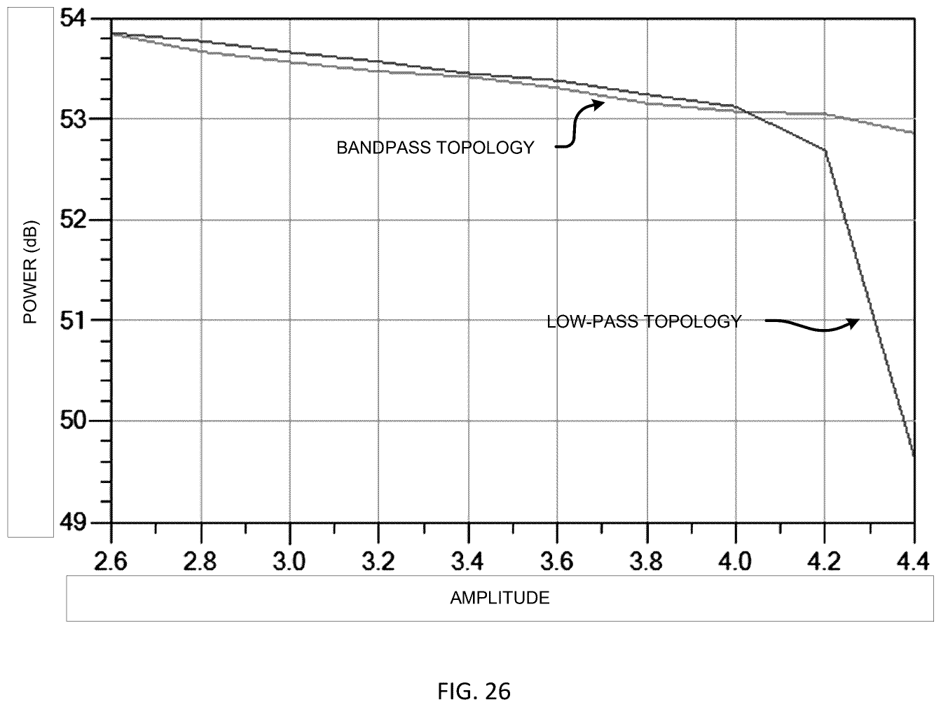

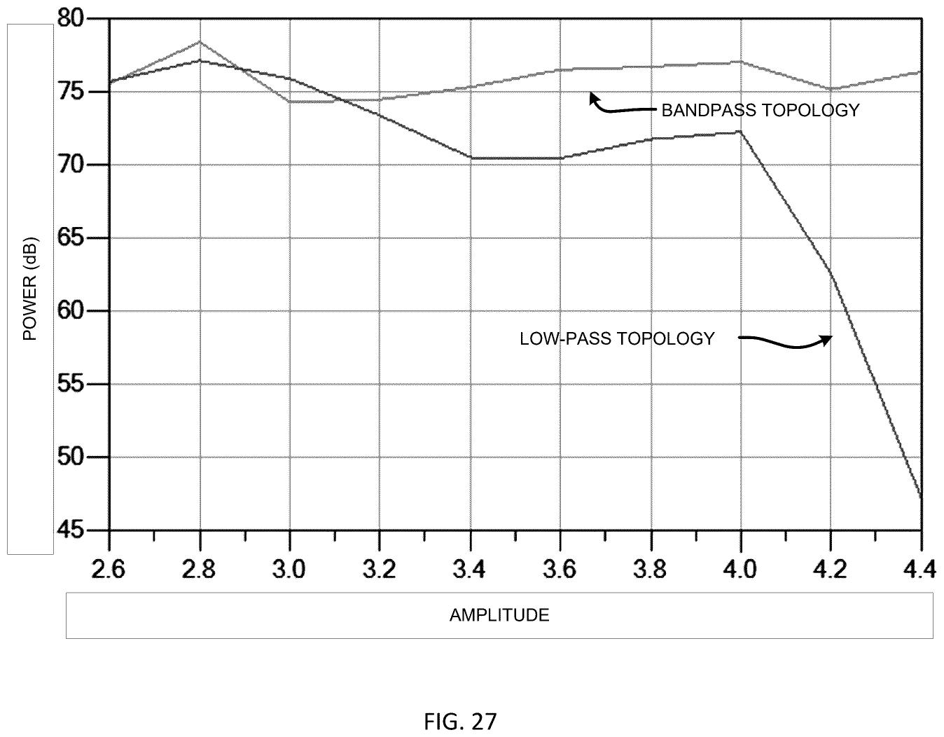

FIG. 26 and FIG. 27 illustrate simulated results of the harmonic reduction circuit and/or the harmonic reduction circuit implementing bandpass topology versus the harmonic reduction circuit and/or the harmonic reduction circuit implementing low-pass topology.

In particular, FIG. 26 and FIG. 27 illustrate simulated results of the harmonic reduction circuit 204 and/or the harmonic reduction circuit 206 implementing bandpass topology versus the harmonic reduction circuit 204 and/or the harmonic reduction circuit 206 implementing low-pass topology. The Zh1 is the impedance looking from a gate of the discrete transistor 200 back into the input matching circuit 104. In aspects, a superior input second harmonic termination may be on capacitors side of a short. Accordingly, the bandpass topology is superior to the low-pass topology for this type of implementation of matching.

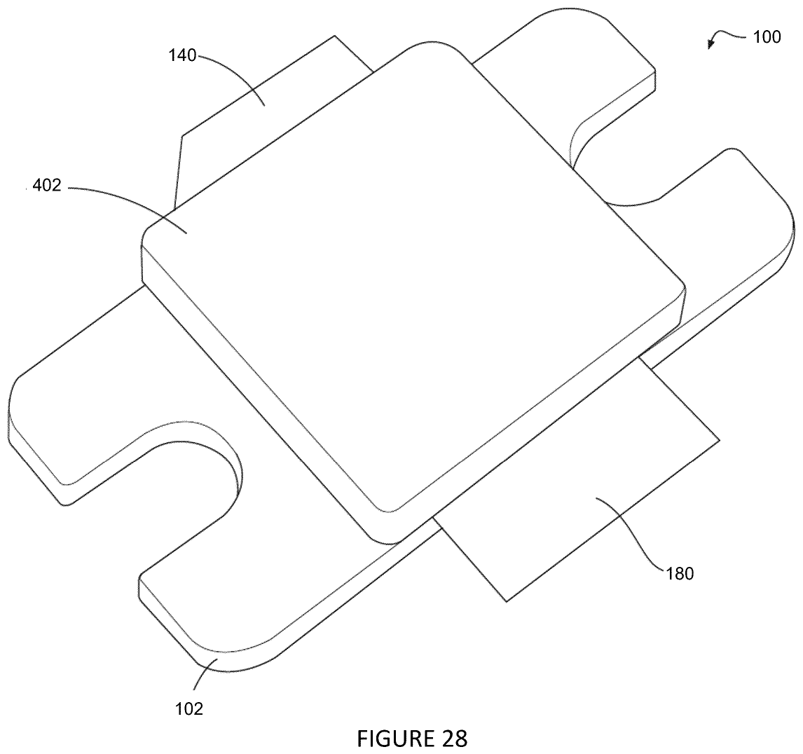

FIG. 28 illustrates a perspective view of a package according to the disclosure.

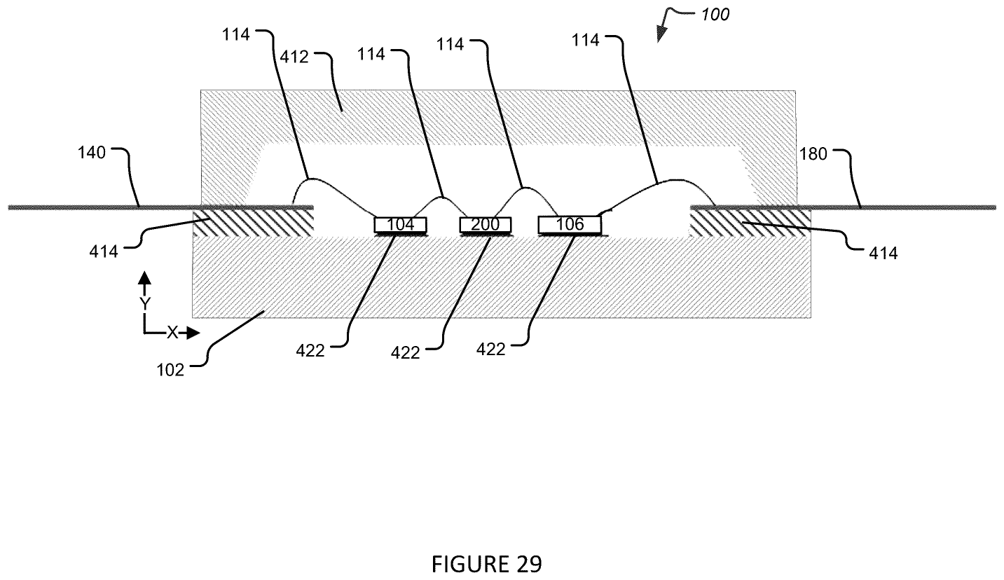

FIG. 29 illustrates a cross-sectional view of the package according to FIG. 28.

FIG. 28 and FIG. 29 may include any one or more other features, components, arrangements, and the like as described herein. In particular, FIG. 28 and FIG. 29 illustrate that the packaged transistor device 100 may be implemented as a RF package, a RF amplifier package, a RF power amplifier package, a RF power transistor package, a RF power amplifier transistor package, and/or the like as described herein. The packaged transistor device 100 may include the input matching circuit 104, the discrete transistor 200, and the output matching circuit 106.

The packaged transistor device 100 may be implemented to include an open cavity configuration suitable for use with the discrete transistor 200 of the disclosure. In particular, the open cavity configuration may utilize an open cavity package design. In some aspects, the open cavity configuration may include a lid or other enclosure for protecting interconnects, circuit components, the discrete transistor 200, and/or the like. The packaged transistor device 100 may include a ceramic lid 412, a ceramic body 414, the RF signal input lead 140, the RF signal output lead 180, the discrete transistor 200, and/or the like.

Inside the packaged transistor device 100, the discrete transistor 200, the input matching circuit 104, and the output matching circuit 106 may be attached to the support component 102 via a die attach material 422. One or more interconnects 114 may couple the discrete transistor 200 to the input matching circuit 104, the output matching circuit 106, the RF signal output lead 180, and the RF signal input lead 140 and/or the like. The one or more interconnects 114 may be implemented as one or more wires, wire bonds, leads, clips, and/or the like.

The support component 102 may dissipate the heat generated by the discrete transistor 200, the input matching circuit 104, the output matching circuit 106, and/or the like. Further, the ceramic lid 412 may isolate and protect the discrete transistor 200, the input matching circuit 104, the output matching circuit 106, and/or the like from the outside environment. In aspects the packaged transistor device 100 may include a plurality of parallel implementations of the RF signal input lead 140, the RF signal output lead 180, the discrete transistor 200, and/or the like.

The support component 102 may be implemented as a metal submount and may be implemented as a support, a surface, a package support, a package surface, a package support surface, a flange, a metal flange, a heat sink, a common source support, a common source surface, a common source package support, a common source package surface, a common source package support surface, a common source flange, a common source heat sink, a leadframe, a metal leadframe and/or the like. The support component 102 may include an insulating material, a dielectric material, and/or the like.

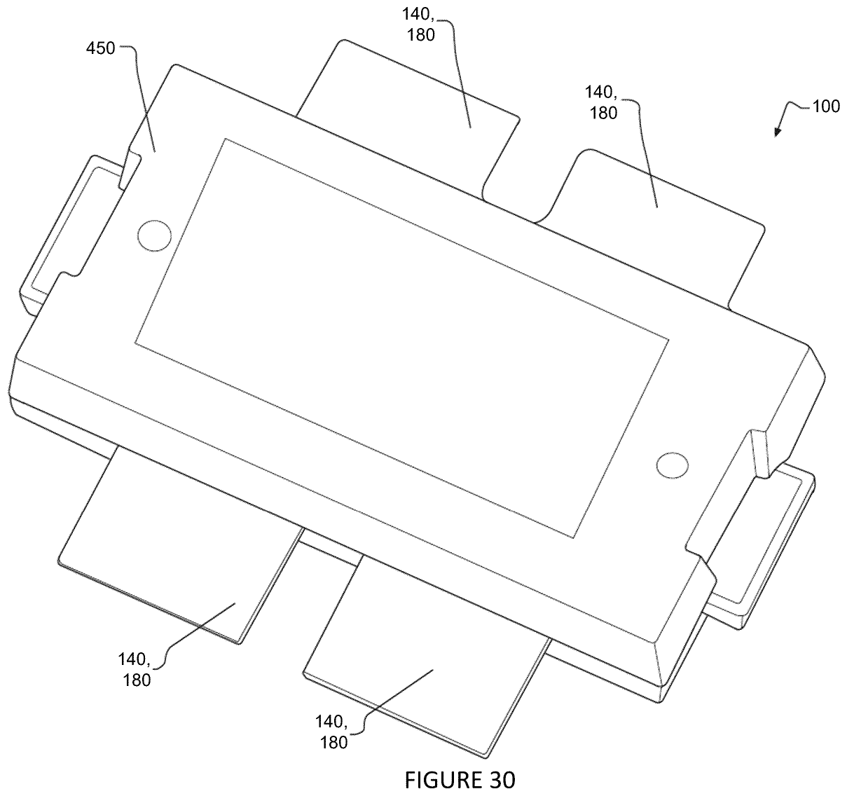

FIG. 30 illustrates a perspective view of a package according to the disclosure.

In aspects, the packaged transistor device 100 may include an over-mold configuration 450 that may substantially surround the RF signal input lead 140, the RF signal output lead 180, the discrete transistor 200 (obscured by the over-mold configuration 450), and/or the like, which are mounted on the support component 102 (obscured by the over-mold configuration 450). The over-mold configuration 450 may be formed of a plastic, a mold compound, a plastic compound, a polymer, a polymer compound, a plastic polymer compound, and/or the like. The over-mold configuration 450 may be injection molded, transfer molded, and/or compression molded around the RF signal input lead 140, the RF signal output lead 180, the discrete transistor 200, and/or the like, thereby providing protection for the RF signal input lead 140, the RF signal output lead 180, the discrete transistor 200, and/or the like from the outside environment.

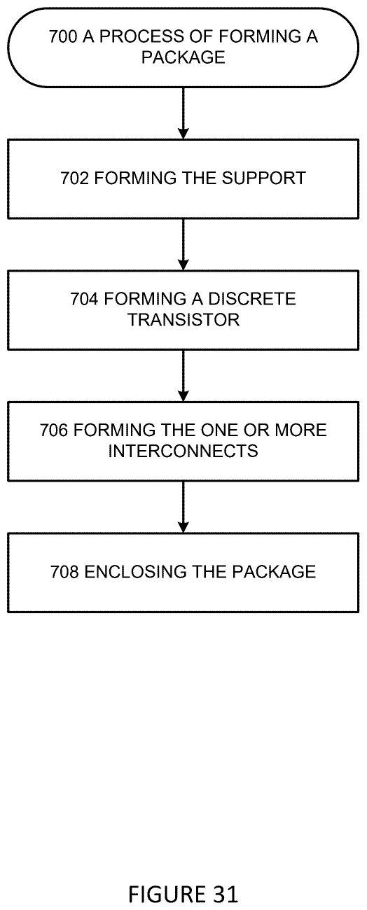

FIG. 31 shows a process of making a package according to the disclosure.

FIG. 31 may include any one or more other features, components, arrangements, and the like as described herein. In particular, FIG. 30 illustrates a process of forming a package 700 that relates to the packaged transistor device 100 as described herein. It should be noted that the aspects of the process of forming a package 700 may be performed in a different order consistent with the aspects described herein. Additionally, it should be noted that portions of the process of forming a package 700 may be performed in a different order consistent with the aspects described herein. Moreover, the process of forming a package 700 may be modified to have more or fewer processes consistent with the various aspects disclosed herein.

Initially, the process of forming a package 700 may include a process of forming the support 702. More specifically, the support component 102 may be constructed, configured, and/or arranged as described herein. In one aspect, the process of forming the support 702 may include forming the support component 102 as a printed circuit board, a MMIC, support, a surface, a package support, a package surface, a package support surface, a flange, a heat sink, a common source heat sink, and/or the like.

The process of forming a package 700 may include the process of forming a discrete transistor 704. More specifically, the process of forming a discrete transistor 704 may include forming the discrete transistor 200 as described herein. In aspects, the process of forming a discrete transistor 704 may include forming the discrete transistor 200 with the harmonic reduction circuit 204 on the substrate 210 as described herein, forming the discrete transistor 200 with the harmonic reduction circuit 206 on the substrate 210 as described herein, forming the discrete transistor 200 with the at least one inductive element 220 on the substrate 210 as described herein, forming the discrete transistor 200 with the at least one capacitor 222 on the substrate 210 as described herein, forming the discrete transistor 200 with the at least one resistor 224 on the substrate 210 as described herein, and/or the like.

Thereafter, the process of forming a discrete transistor 704 may further include attaching the discrete transistor 200 to the support component 102. In this regard, the discrete transistor 200 may be mounted on the upper surface of the support component 102 by an adhesive, soldering, sintering, eutectic bonding, ultrasonically welding, and/or the like as described herein. Additionally, the input matching circuit 104 and/or the output matching circuit 106 may be mounted on the upper surface of the support component 102 by an adhesive, soldering, sintering, eutectic bonding, ultrasonically welding, and/or the like as described herein.

The process of forming a package 700 may include a process of forming the one or more interconnects 706. More specifically, the one or more interconnects 114 may be constructed, configured, and/or arranged as described herein. In one aspect, the process of forming the one or more interconnects 706 may include forming the one or more interconnects 114 by forming one or more wires, leads, vias, edge platings, circuit traces, tracks, and/or the like. In one aspect, the process of forming the one or more interconnects 706 may include connecting the one or more interconnects 706 by an adhesive, soldering, sintering, eutectic bonding, ultrasonic welding, a clip component, and/or the like as described herein.

The process of forming a package 700 may include a process of enclosing the package 708. More specifically, the packaged transistor device 100 may be constructed, configured, and/or arranged as described herein. In one aspect, the process of enclosing the package 708 may include forming an open cavity configuration, an over-mold configuration, and/or the like.

In one aspect, the process of forming a package 700 may include processing utilizing a surface mount technology (SMT) line. A surface mount technology (SMT) line may utilize numerous processes including solder printing, component placement, solder reflow, and/or the like. Additional processes may include a flux cleaning step to remove all flux residues, wire bonding, dicing, mounting to dicing tape, dicing, either mechanical sawing or laser cutting, or a combination of both, and component testing. Additionally, the discrete transistor 200 may be arranged on dicing tape that may then serve as input for the Die Attach equipment.

The packaged transistor device 100 may be implemented as an RF package and the discrete transistor 200 may be implemented as a radio frequency device that may include, connect, support, or the like a transmitter, transmitter functions, a receiver, receiver functions, a transceiver, transceiver functions, matching network functions, harmonic termination circuitry, and the like. The discrete transistor 200 may be implemented as a radio frequency device may be configured to, may support, or the like transmitting a radio wave and modulating that wave to carry data with allowable transmitter power output, harmonics, and/or band edge requirements. The discrete transistor 200 device may be configured to, may support, or the like receiving a radio wave and demodulating the radio wave. The discrete transistor 200 implemented as a radio frequency device may be configured to, may support, or the like transmitting a radio wave and modulating that wave to carry data with allowable transmitter power output, harmonics, and/or band edge requirements; and may be configured to, may support, or the like receiving a radio wave and demodulating the radio wave. The packaged transistor device 100 may be implemented in any number of different applications. In this regard, the packaged transistor device 100 may be implemented in applications implementing high video bandwidth power amplifier transistors, a single path radio frequency power transistor, a single stage radio frequency power transistor, a multipath radio frequency power transistor, a Doherty configuration a multistage radio frequency power transistor, a GaN based radio frequency power amplifier module, a laterally-diffused metal-oxide semiconductor (LDMOS) device, a LDMOS radio frequency power amplifier module, a radio frequency power device, an ultra-wideband device, a GaN based device, a Metal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), a Wide Band Gap (WBG) semiconductor, a power module, a gate driver, a component such as a General-Purpose Broadband component, a Telecom component, a L-Band component, a S-Band component, a X-Band component, a C-Band component, a Ku-Band component, a Satellite Communications component, and/or the like. The packaged transistor device 100 may be implemented as a power package. The packaged transistor device 100 may be implemented as a power package and may implement applications and components as described herein.

The packaged transistor device 100 may be implemented as a radio frequency package. The packaged transistor device 100 may be implemented as a radio frequency package and may implement applications and components as described herein. The packaged transistor device 100 implemented as a radio frequency package may include, connect, support, or the like a transmitter, transmitter functions, a receiver, receiver functions, a transceiver, transceiver functions, and the like. The packaged transistor device 100 implemented as a radio frequency package may be configured to, may support, or the like transmitting a radio wave and modulating that wave to carry data with allowable transmitter power output, harmonics, and/or band edge requirements. The packaged transistor device 100 implemented as a radio frequency package may be configured to, may support, or the like receiving a radio wave and demodulating the radio wave. The packaged transistor device 100 implemented as a radio frequency package may be configured to, may support, or the like transmitting a radio wave and modulating out that wave to carry data with allowable transmitter power output, harmonics, and/or band edge requirements; and may be configured to, may support, or the like receiving a radio wave and demodulating the radio wave.

The packaged transistor device 100 implementing the discrete transistor 200 having the harmonic reduction circuit 204 and/or the harmonic reduction circuit 206 within the discrete transistor 200 may be useful in a wide range of applications in which linearity is important. For example, a packaged power transistor according to embodiments of the invention may have application in systems, such as LTE, NR, 5G and future 6G systems. In general, embodiments of the invention may be useful in any application in which linear performance is desired from a power transistor.

Accordingly, the disclosure has set forth radio frequency (RF) power transistor configurations having greater linearity during high-frequency operation is needed.

One EXAMPLE: a packaged transistor device includes an RF signal input lead. The packaged transistor device in addition includes an RF signal output lead. The packaged transistor device moreover includes a discrete transistor comprising a transistor structure arranged and/or formed on a substrate. The packaged transistor device also includes at least one harmonic reduction circuit arranged and/or formed on the substrate of the discrete transistor.

The above-noted EXAMPLE may further include any one or a combination of more than one of the following EXAMPLES: The packaged transistor device of the above-noted EXAMPLE where the discrete transistor is configured to connect the at least one harmonic reduction circuit to a control electrode of the transistor structure. The packaged transistor device of the above-noted EXAMPLE where the at least one harmonic reduction circuit is coupled to an output electrode of the transistor structure. The packaged transistor device of the above-noted EXAMPLE where the substrate comprises silicon carbide (SiC). The packaged transistor device of the above-noted EXAMPLE where the discrete transistor is implemented as a gallium nitride (GaN) silicon carbide (SiC) transistor. The packaged transistor device of the above-noted EXAMPLE includes an input matching circuit and/or an output matching circuit. The packaged transistor device of the above-noted EXAMPLE where a structure of the at least one harmonic reduction circuit is arranged at least partially on the substrate, is arranged at least partially on the transistor structure, and/or is arranged at least partially on the substrate and the transistor structure. The packaged transistor device of the above-noted EXAMPLE where a structure of the transistor structure is arranged at least partially on the substrate and/or is arranged at least partially on the at least one harmonic reduction circuit. The packaged transistor device of the above-noted EXAMPLE where the at least one harmonic reduction circuit comprises at least one inductive element, at least one capacitor, and/or at least one resistor. The packaged transistor device of the above-noted EXAMPLE where the at least one capacitor comprises at least one dielectric layer, at least one capacitor top metal, at least one capacitor bottom metal; and where the at least one capacitor forms a capacitor with the at least one capacitor top metal and the at least one capacitor bottom metal having the at least one dielectric layer therebetween. The packaged transistor device of the above-noted EXAMPLE where a structure of the at least one capacitor is arranged at least partially on the substrate, is arranged at least partially on the transistor structure, and/or is arranged at least partially on the substrate and the transistor structure. The packaged transistor device of the above-noted EXAMPLE where the at least one inductive element comprises at least one inductor metal; and where the at least one inductive element forms an inductor by arrangement of the at least one inductor metal on the substrate of the discrete transistor. The packaged transistor device of the above-noted EXAMPLE where a structure of the at least one inductive element is arranged at least partially on the substrate, is arranged at least partially on the transistor structure, and/or is arranged at least partially on the substrate and the transistor structure. The packaged transistor device of the above-noted EXAMPLE where a structure of the at least one inductive element is arranged at least partially on the substrate, is arranged at least partially on the transistor structure, is arranged at least partially on the substrate and the transistor structure, and/or is arranged at least partially on the at least one capacitor. The packaged transistor device of the above-noted EXAMPLE where an inductance of the at least one inductive element and a capacitance of the at least one capacitor is selected to provide a bandpass implementation. The packaged transistor device of the above-noted EXAMPLE where an inductance of the at least one inductive element and a capacitance of the at least one capacitor is selected to provide a short circuit and/or low impedance path to ground for signals at a harmonic frequency. The packaged transistor device of the above-noted EXAMPLE where the at least one harmonic reduction circuit comprises an implementation of the at least one inductive element in series with an implementation of the at least one capacitor and the at least one harmonic reduction circuit. The packaged transistor device of the above-noted EXAMPLE where the at least one harmonic reduction circuit comprises the at least one inductive element in series with the at least one capacitor; and where the at least one harmonic reduction circuit comprises another implementation of the at least one inductive element in series with another implementation of the at least one capacitor. The packaged transistor device of the above-noted EXAMPLE where the at least one capacitor is buried underneath one or more bond pads of the discrete transistor. The packaged transistor device of the above-noted EXAMPLE where the at least one inductive element is between implementations of one or more bond pads of the discrete transistor. The packaged transistor device of the above-noted EXAMPLE where the at least one inductive element is printed between implementations of one or more bond pads of the discrete transistor. The packaged transistor device of the above-noted EXAMPLE where the at least one inductive element is arranged on the substrate adjacent the at least one capacitor. The packaged transistor device of the above-noted EXAMPLE where the at least one inductive element is connected to the at least one capacitor and one or more vias. The packaged transistor device of the above-noted EXAMPLE where the at least one harmonic reduction circuit is implemented by absorbing the at least one inductive element into a fundamental match as a bandpass structure. The packaged transistor device of the above-noted EXAMPLE where the discrete transistor comprises one or more bond pads; and where the one or more bond pads connect to an input matching circuit, an output matching circuit, the RF signal input lead, and/or the RF signal output lead. The packaged transistor device of the above-noted EXAMPLE where at least one capacitor is arranged on the substrate and adjacent at least one resistor; and where the at least one resistor is arranged on the substrate and adjacent one or more bond pads and the at least one capacitor. The packaged transistor device of the above-noted EXAMPLE where one or more bond pads are connected to a drain bus of the transistor structure. The packaged transistor device of the above-noted EXAMPLE where one or more bond pads are connected to a gate bus of the transistor structure. The packaged transistor device of the above-noted EXAMPLE where the at least one harmonic reduction circuit comprises two implementations of the at least one harmonic reduction circuit. The packaged transistor device of the above-noted EXAMPLE includes: an open cavity configuration; a support component; and one or more interconnects coupled to the discrete transistor, an input matching circuit, an output matching circuit, the RF signal output lead, and/or the RF signal input lead. The packaged transistor device of the above-noted EXAMPLE includes: an over-mold configuration; a support component; and one or more interconnects coupled to the discrete transistor, an input matching circuit, an output matching circuit, the RF signal output lead, and/or the RF signal input lead.

One EXAMPLE: a process includes providing an RF signal input lead. The process in addition includes providing an RF signal output lead. The process moreover includes forming and arranging a discrete transistor comprising a transistor structure on a substrate. The process also includes forming and arranging at least one harmonic reduction circuit on the substrate of the discrete transistor.

The above-noted EXAMPLE may further include any one or a combination of more than one of the following EXAMPLES: The process of the above-noted EXAMPLE where the discrete transistor is configured to connect the at least one harmonic reduction circuit to a control electrode of the transistor structure. The process of the above-noted EXAMPLE where the at least one harmonic reduction circuit is coupled to an output electrode of the transistor structure. The process of the above-noted EXAMPLE where the substrate comprises silicon carbide (SiC). The process of the above-noted EXAMPLE where the discrete transistor is implemented as a gallium nitride (GaN) silicon carbide (SiC) transistor. The process of the above-noted EXAMPLE includes an input matching circuit and/or an output matching circuit. The process of the above-noted EXAMPLE where a structure of the at least one harmonic reduction circuit is arranged at least partially on the substrate, is arranged at least partially on the transistor structure, and/or is arranged at least partially on the substrate and the transistor structure. The process of the above-noted EXAMPLE where a structure of the transistor structure is arranged at least partially on the substrate and/or is arranged at least partially on the at least one harmonic reduction circuit. The process of the above-noted EXAMPLE where the at least one harmonic reduction circuit comprises at least one inductive element, at least one capacitor, and/or at least one resistor. The packaged transistor device of the above-noted EXAMPLE where the at least one capacitor comprises at least one dielectric layer, at least one capacitor top metal, at least one capacitor bottom metal; and where the at least one capacitor forms a capacitor with the at least one capacitor top metal and the at least one capacitor bottom metal having the at least one dielectric layer therebetween. The packaged transistor device of the above-noted EXAMPLE where a structure of the at least one capacitor is arranged at least partially on the substrate, is arranged at least partially on the transistor structure, and/or is arranged at least partially on the substrate and the transistor structure. The packaged transistor device of the above-noted EXAMPLE where the at least one inductive element comprises at least one inductor metal; and where the at least one inductive element forms an inductor by arrangement of the at least one inductor metal on the substrate of the discrete transistor. The packaged transistor device of the above-noted EXAMPLE where a structure of the at least one inductive element is arranged at least partially on the substrate, is arranged at least partially on the transistor structure, and/or is arranged at least partially on the substrate and the transistor structure. The packaged transistor device of the above-noted EXAMPLE where a structure of the at least one inductive element is arranged at least partially on the substrate, is arranged at least partially on the transistor structure, is arranged at least partially on the substrate and the transistor structure, and/or is arranged at least partially on the at least one capacitor. The packaged transistor device of the above-noted EXAMPLE where an inductance of the at least one inductive element and a capacitance of the at least one capacitor is selected to provide a bandpass implementation. The packaged transistor device of the above-noted EXAMPLE where an inductance of the at least one inductive element and a capacitance of the at least one capacitor is selected to provide a short circuit and/or low impedance path to ground for signals at a harmonic frequency. The packaged transistor device of the above-noted EXAMPLE where the at least one harmonic reduction circuit comprises an implementation of the at least one inductive element in series with an implementation of the at least one capacitor and the at least one harmonic reduction circuit. The packaged transistor device of the above-noted EXAMPLE where the at least one harmonic reduction circuit comprises the at least one inductive element in series with the at least one capacitor; and where the at least one harmonic reduction circuit comprises another implementation of the at least one inductive element in series with another implementation of the at least one capacitor. The packaged transistor device of the above-noted EXAMPLE where the at least one capacitor is buried underneath one or more bond pads of the discrete transistor. The packaged transistor device of the above-noted EXAMPLE where the at least one inductive element is between implementations of one or more bond pads of the discrete transistor. The packaged transistor device of the above-noted EXAMPLE where the at least one inductive element is printed between implementations of one or more bond pads of the discrete transistor. The packaged transistor device of the above-noted EXAMPLE where the at least one inductive element is arranged on the substrate adjacent the at least one capacitor. The packaged transistor device of the above-noted EXAMPLE where the at least one inductive element is connected to the at least one capacitor and one or more vias. The packaged transistor device of the above-noted EXAMPLE where the at least one harmonic reduction circuit is implemented by absorbing the at least one inductive element into a fundamental match as a bandpass structure. The process of the above-noted EXAMPLE where the discrete transistor comprises one or more bond pads; and where the one or more bond pads connect to an input matching circuit, an output matching circuit, the RF signal input lead, and/or the RF signal output lead. The process of the above-noted EXAMPLE where at least one capacitor is arranged on the substrate and adjacent at least one resistor; and where the at least one resistor is arranged on the substrate and adjacent one or more bond pads and the at least one capacitor. The process of the above-noted EXAMPLE where one or more bond pads are connected to a drain bus of the transistor structure. The process of the above-noted EXAMPLE where one or more bond pads are connected to a gate bus of the transistor structure. The process of the above-noted EXAMPLE where the at least one harmonic reduction circuit comprises two implementations of the at least one harmonic reduction circuit. The process of the above-noted EXAMPLE includes: providing a support component; coupling one or more interconnects to the discrete transistor, an input matching circuit, an output matching circuit, the RF signal output lead, and/or the RF signal input lead; and forming an open cavity configuration. The process of the above-noted EXAMPLE includes: providing a support component; coupling one or more interconnects to the discrete transistor, an input matching circuit, an output matching circuit, the RF signal output lead, and/or the RF signal input lead; and forming an over-mold configuration.

One EXAMPLE: a packaged transistor device includes an RF signal input lead. The packaged transistor device in addition includes an RF signal output lead. The packaged transistor device moreover includes a discrete transistor comprising a transistor structure arranged and/or formed on a substrate. The packaged transistor device also includes at least one harmonic reduction circuit arranged and/or formed on the substrate of the discrete transistor. The packaged transistor device further includes where a structure of the at least one harmonic reduction circuit is arranged at least partially on the substrate, is arranged at least partially on the transistor structure, and/or is arranged at least partially on the substrate and the transistor structure.

The above-noted EXAMPLE may further include any one or a combination of more than one of the following EXAMPLES: The packaged transistor device of the above-noted EXAMPLE where the discrete transistor is configured to connect the at least one harmonic reduction circuit to a control electrode of the transistor structure. The packaged transistor device of the above-noted EXAMPLE where the at least one harmonic reduction circuit is coupled to an output electrode of the transistor structure. The packaged transistor device of the above-noted EXAMPLE where the substrate comprises silicon carbide (SiC). The packaged transistor device of the above-noted EXAMPLE where the discrete transistor is implemented as a gallium nitride (GaN) silicon carbide (SiC) transistor. The packaged transistor device of the above-noted EXAMPLE includes an input matching circuit and/or an output matching circuit. The packaged transistor device of the above-noted EXAMPLE where a structure of the transistor structure is arranged at least partially on the substrate and/or is arranged at least partially on the at least one harmonic reduction circuit. The packaged transistor device of the above-noted EXAMPLE where the at least one harmonic reduction circuit comprises at least one inductive element, at least one capacitor, and/or at least one resistor. The packaged transistor device of the above-noted EXAMPLE where the at least one capacitor comprises at least one dielectric layer, at least one capacitor top metal, at least one capacitor bottom metal; and where the at least one capacitor forms a capacitor with the at least one capacitor top metal and the at least one capacitor bottom metal having the at least one dielectric layer therebetween. The packaged transistor device of the above-noted EXAMPLE where a structure of the at least one capacitor is arranged at least partially on the substrate, is arranged at least partially on the transistor structure, and/or is arranged at least partially on the substrate and the transistor structure. The packaged transistor device of the above-noted EXAMPLE where the at least one inductive element comprises at least one inductor metal; and where the at least one inductive element forms an inductor by arrangement of the at least one inductor metal on the substrate of the discrete transistor. The packaged transistor device of the above-noted EXAMPLE where a structure of the at least one inductive element is arranged at least partially on the substrate, is arranged at least partially on the transistor structure, and/or is arranged at least partially on the substrate and the transistor structure. The packaged transistor device of the above-noted EXAMPLE where a structure of the at least one inductive element is arranged at least partially on the substrate, is arranged at least partially on the transistor structure, is arranged at least partially on the substrate and the transistor structure, and/or is arranged at least partially on the at least one capacitor. The packaged transistor device of the above-noted EXAMPLE where an inductance of the at least one inductive element and a capacitance of the at least one capacitor is selected to provide a bandpass implementation. The packaged transistor device of the above-noted EXAMPLE where an inductance of the at least one inductive element and a capacitance of the at least one capacitor is selected to provide a short circuit and/or low impedance path to ground for signals at a harmonic frequency. The packaged transistor device of the above-noted EXAMPLE where the at least one harmonic reduction circuit comprises an implementation of the at least one inductive element in series with an implementation of the at least one capacitor and the at least one harmonic reduction circuit. The packaged transistor device of the above-noted EXAMPLE where the at least one harmonic reduction circuit comprises the at least one inductive element in series with the at least one capacitor; and where the at least one harmonic reduction circuit comprises another implementation of the at least one inductive element in series with another implementation of the at least one capacitor. The packaged transistor device of the above-noted EXAMPLE where the at least one capacitor is buried underneath one or more bond pads of the discrete transistor. The packaged transistor device of the above-noted EXAMPLE where the at least one inductive element is between implementations of one or more bond pads of the discrete transistor. The packaged transistor device of the above-noted EXAMPLE where the at least one inductive element is printed between implementations of one or more bond pads of the discrete transistor. The packaged transistor device of the above-noted EXAMPLE where the at least one inductive element is arranged on the substrate adjacent the at least one capacitor. The packaged transistor device of the above-noted EXAMPLE where the at least one inductive element is connected to the at least one capacitor and one or more vias. The packaged transistor device of the above-noted EXAMPLE where the at least one harmonic reduction circuit is implemented by absorbing the at least one inductive element into a fundamental match as a bandpass structure. The packaged transistor device of the above-noted EXAMPLE where the discrete transistor comprises one or more bond pads; and where the one or more bond pads connect to an input matching circuit, an output matching circuit, the RF signal input lead, and/or the RF signal output lead. The packaged transistor device of the above-noted EXAMPLE where at least one capacitor is arranged on the substrate and adjacent at least one resistor; and where the at least one resistor is arranged on the substrate and adjacent one or more bond pads and the at least one capacitor. The packaged transistor device of the above-noted EXAMPLE where one or more bond pads are connected to a drain bus of the transistor structure. The packaged transistor device of the above-noted EXAMPLE where one or more bond pads are connected to a gate bus of the transistor structure. The packaged transistor device of the above-noted EXAMPLE where the at least one harmonic reduction circuit comprises two implementations of the at least one harmonic reduction circuit. The packaged transistor device of the above-noted EXAMPLE includes: an open cavity configuration; a support component; and one or more interconnects coupled to the discrete transistor, an input matching circuit, an output matching circuit, the RF signal output lead, and/or the RF signal input lead. The packaged transistor device of the above-noted EXAMPLE includes: an over-mold configuration; a support component; and one or more interconnects coupled to the discrete transistor, an input matching circuit, an output matching circuit, the RF signal output lead, and/or the RF signal input lead.

One EXAMPLE: a process includes providing an RF signal input lead. The process in addition includes providing an RF signal output lead. The process moreover includes forming and arranging a discrete transistor comprising a transistor structure on a substrate. The process also includes forming and arranging at least one harmonic reduction circuit on the substrate of the discrete transistor. The process further includes where a structure of the at least one harmonic reduction circuit is arranged at least partially on the substrate, is arranged at least partially on the transistor structure, and/or is arranged at least partially on the substrate and the transistor structure.

The above-noted EXAMPLE may further include any one or a combination more than one of the following EXAMPLES: The process of the above-noted EXAMPLE where the discrete transistor is configured to connect the at least one harmonic reduction circuit to a control electrode of the transistor structure. The process of the above-noted EXAMPLE where the at least one harmonic reduction circuit is coupled to an output electrode of the transistor structure. The process of the above-noted EXAMPLE where the substrate comprises silicon carbide (SiC). The process of the above-noted EXAMPLE where the discrete transistor is implemented as a gallium nitride (GaN) silicon carbide (SiC) transistor. The process of the above-noted EXAMPLE includes an input matching circuit and/or an output matching circuit. The process of the above-noted EXAMPLE where a structure of the transistor structure is arranged at least partially on the substrate and/or is arranged at least partially on the at least one harmonic reduction circuit. The process of the above-noted EXAMPLE where the at least one harmonic reduction circuit comprises at least one inductive element, at least one capacitor, and/or at least one resistor. The packaged transistor device of the above-noted EXAMPLE where the at least one capacitor comprises at least one dielectric layer, at least one capacitor top metal, at least one capacitor bottom metal; and where the at least one capacitor forms a capacitor with the at least one capacitor top metal and the at least one capacitor bottom metal having the at least one dielectric layer therebetween. The packaged transistor device of the above-noted EXAMPLE where a structure of the at least one capacitor is arranged at least partially on the substrate, is arranged at least partially on the transistor structure, and/or is arranged at least partially on the substrate and the transistor structure. The packaged transistor device of the above-noted EXAMPLE where the at least one inductive element comprises at least one inductor metal; and where the at least one inductive element forms an inductor by arrangement of the at least one inductor metal on the substrate of the discrete transistor. The packaged transistor device of the above-noted EXAMPLE where a structure of the at least one inductive element is arranged at least partially on the substrate, is arranged at least partially on the transistor structure, and/or is arranged at least partially on the substrate and the transistor structure. The packaged transistor device of the above-noted EXAMPLE where a structure of the at least one inductive element is arranged at least partially on the substrate, is arranged at least partially on the transistor structure, is arranged at least partially on the substrate and the transistor structure, and/or is arranged at least partially on the at least one capacitor. The packaged transistor device of the above-noted EXAMPLE where an inductance of the at least one inductive element and a capacitance of the at least one capacitor is selected to provide a bandpass implementation. The packaged transistor device of the above-noted EXAMPLE where an inductance of the at least one inductive element and a capacitance of the at least one capacitor is selected to provide a short circuit and/or low impedance path to ground for signals at a harmonic frequency. The packaged transistor device of the above-noted EXAMPLE where the at least one harmonic reduction circuit comprises an implementation of the at least one inductive element in series with an implementation of the at least one capacitor and the at least one harmonic reduction circuit. The packaged transistor device of the above-noted EXAMPLE where the at least one harmonic reduction circuit comprises the at least one inductive element in series with the at least one capacitor; and where the at least one harmonic reduction circuit comprises another implementation of the at least one inductive element in series with another implementation of the at least one capacitor. The packaged transistor device of the above-noted EXAMPLE where the at least one capacitor is buried underneath one or more bond pads of the discrete transistor. The packaged transistor device of the above-noted EXAMPLE where the at least one inductive element is between implementations of one or more bond pads of the discrete transistor. The packaged transistor device of the above-noted EXAMPLE where the at least one inductive element is printed between implementations of one or more bond pads of the discrete transistor. The packaged transistor device of the above-noted EXAMPLE where the at least one inductive element is arranged on the substrate adjacent the at least one capacitor. The packaged transistor device of the above-noted EXAMPLE where the at least one inductive element is connected to the at least one capacitor and one or more vias. The packaged transistor device of the above-noted EXAMPLE where the at least one harmonic reduction circuit is implemented by absorbing the at least one inductive element into a fundamental match as a bandpass structure. The process of the above-noted EXAMPLE where the discrete transistor comprises one or more bond pads; and where the one or more bond pads connect to an input matching circuit, an output matching circuit, the RF signal input lead, and/or the RF signal output lead. The process of the above-noted EXAMPLE where at least one capacitor is arranged on the substrate and adjacent at least one resistor; and where the at least one resistor is arranged on the substrate and adjacent one or more bond pads and the at least one capacitor. The process of the above-noted EXAMPLE where one or more bond pads are connected to a drain bus of the transistor structure. The process of the above-noted EXAMPLE where one or more bond pads are connected to a gate bus of the transistor structure. The process of the above-noted EXAMPLE where the at least one harmonic reduction circuit comprises two implementations of the at least one harmonic reduction circuit. The process of the above-noted EXAMPLE includes: providing a support component; coupling one or more interconnects to the discrete transistor, an input matching circuit, an output matching circuit, the RF signal output lead, and/or the RF signal input lead; and forming an open cavity configuration. The process of the above-noted EXAMPLE includes: providing a support component; coupling one or more interconnects to the discrete transistor, an input matching circuit, an output matching circuit, the RF signal output lead, and/or the RF signal input lead; and forming an over-mold configuration.

The adhesive of the disclosure may be utilized in an adhesive bonding process that may include applying an intermediate layer to connect surfaces to be connected. The adhesive may be organic or inorganic; and the adhesive may be deposited on one or both surfaces of the surface to be connected. The adhesive may be utilized in an adhesive bonding process that may include applying adhesive material with a particular coating thickness, at a particular bonding temperature, for a particular processing time while in an environment that may include applying a particular tool pressure. In one aspect, the adhesive may be a conductive adhesive, an epoxy-based adhesive, a conductive epoxy-based adhesive, and/or the like.

The solder of the disclosure may be utilized to form a solder interface that may include solder and/or be formed from solder. The solder may be any fusible metal alloy that may be used to form a bond between surfaces to be connected. The solder may be a lead-free solder, a lead solder, a eutectic solder, or the like. The lead-free solder may contain tin, copper, silver, bismuth, indium, zinc, antimony, traces of other metals, and/or the like. The lead solder may contain lead, other metals such as tin, silver, and/or the like. The solder may further include flux as needed.

The sintering of the disclosure may utilize a process of compacting and forming a conductive mass of material by heat and/or pressure. The sintering process may operate without melting the material to the point of liquefaction. The sintering process may include sintering of metallic nano or hybrid powders in pastes or epoxies. The sintering process may include sintering in a vacuum. The sintering process may include sintering with the use of a protective gas.

The eutectic bonding of the disclosure may utilize a eutectic soldering process that may form a eutectic system. The eutectic system may be used between surfaces to be connected. The eutectic bonding may utilize metals that may be alloys and/or intermetallics that transition from solid to liquid state, or from liquid to solid state, at a specific composition and temperature. The eutectic alloys may be deposited by sputtering, evaporation, electroplating, and/or the like.

The ultrasonically welding of the disclosure may utilize a process whereby high-frequency ultrasonic acoustic vibrations are locally applied to components being held together under pressure. The ultrasonically welding may create a solid-state weld between surfaces to be connected. In one aspect, the ultrasonically welding may include applying a sonicated force.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A packaged transistor device comprising:
an RF signal input lead;
an RF signal output lead;
a discrete transistor comprising a transistor structure arranged and/or formed on a substrate; and
at least one harmonic reduction circuit arranged and/or formed on the substrate of the discrete transistor.

2. The packaged transistor device according to claim 1, wherein the discrete transistor is configured to connect the at least one harmonic reduction circuit to a control electrode of the transistor structure.

3. The packaged transistor device according to claim 1, wherein the at least one harmonic reduction circuit is coupled to an output electrode of the transistor structure.

4. The packaged transistor device according to claim 1, wherein the substrate comprises silicon carbide (SiC).

5. (canceled)

6. The packaged transistor device according to claim 1, further comprising an input matching circuit and/or an output matching circuit.

7. The packaged transistor device according to claim 1, wherein a structure of the at least one harmonic reduction circuit is arranged at least partially on the substrate, is arranged at least partially on the transistor structure, and/or is arranged at least partially on the substrate and the transistor structure.

8. The packaged transistor device according to claim 1, wherein a structure of the transistor structure is arranged at least partially on the substrate and/or is arranged at least partially on the at least one harmonic reduction circuit.

9. The packaged transistor device according to claim 1, wherein the at least one harmonic reduction circuit comprises at least one inductive element, at least one capacitor, and/or at least one resistor.

10. The packaged transistor device according to claim 9,
wherein the at least one capacitor comprises at least one dielectric layer, at least one capacitor top metal, at least one capacitor bottom metal; and
wherein the at least one capacitor forms a capacitor with the at least one capacitor top metal and the at least one capacitor bottom metal having the at least one dielectric layer therebetween.

11. The packaged transistor device according to claim 9, wherein a structure of the at least one capacitor is arranged at least partially on the substrate, is arranged at least partially on the transistor structure, and/or is arranged at least partially on the substrate and the transistor structure.

12. The packaged transistor device according to claim 9,
wherein the at least one inductive element comprises at least one inductor metal; and
wherein the at least one inductive element forms an inductor by arrangement of the at least one inductor metal on the substrate of the discrete transistor.

13. The packaged transistor device according to claim 9, wherein a structure of the at least one inductive element comprises at least one inductor metal arranged at least partially on the substrate, is arranged at least partially on the transistor structure, and/or is arranged at least partially on the substrate and the transistor structure.

14. The packaged transistor device according to claim 9, wherein a structure of the at least one inductive element is arranged at least partially on the substrate, is arranged at least partially on the transistor structure, is arranged at least partially on the substrate and the transistor structure, and/or is arranged at least partially on the at least one capacitor.

15-18. (canceled)

19. The packaged transistor device according to claim 9, wherein the at least one capacitor is buried underneath one or more bond pads of the discrete transistor.

20. The packaged transistor device according to claim 9,
wherein the at least one capacitor is buried underneath one or more bond pads of the discrete transistor; and
wherein the at least one inductive element is arranged in a whitespace of the transistor structure.

21. The packaged transistor device according to claim 9,
wherein the at least one capacitor is arranged in a whitespace of the transistor structure; and
wherein the at least one inductive element is arranged in a whitespace of the transistor structure.

22. The packaged transistor device according to claim 9, wherein the at least one inductive element is between implementations of one or more bond pads of the discrete transistor.

23-33. (canceled)

34. The packaged transistor device according to claim 1, further comprising:
an over-mold configuration;
a support component; and
one or more interconnects coupled to the discrete transistor, an input matching circuit, an output matching circuit, the RF signal output lead, and/or the RF signal input lead.

35. A process of implementing a packaged transistor device comprising:
providing an RF signal input lead;
providing an RF signal output lead;
forming and arranging a discrete transistor comprising a transistor structure on a substrate; and
forming and arranging at least one harmonic reduction circuit on the substrate of the discrete transistor.

36-68. (canceled)

69. A packaged transistor device comprising:
an RF signal input lead;
an RF signal output lead;
a discrete transistor comprising a transistor structure arranged and/or formed on a substrate; and
at least one harmonic reduction circuit arranged and/or formed on the substrate of the discrete transistor,
wherein a structure of the at least one harmonic reduction circuit is arranged at least partially on the substrate, is arranged at least partially on the transistor structure, and/or is arranged at least partially on the substrate and the transistor structure.

70-134. (canceled)
